(19) United States
(12) Patent Application Publication
(10) Pub. No.: US 2026/0194982 A1
(43) Pub. Date: Jul. 9, 2026

(54) ADAPTIVE COMPRESSION FIT FOR REFERRED SENSATION WEARABLE

(71) Applicant: Afference Inc., Boulder, CO (US)

(72) Inventors: Jacob Segil, Boulder, CO (US); Dustin Tyler, Boulder, CO (US); Jeremy Dunning, Boulder, CO (US); Rachel Jakes, Boulder, CO (US); Laura McGann, Boulder, CO (US)

(21) Appl. No.: 19/421,140

(22) Filed: Dec. 16, 2025

Related U.S. Application Data
(60) Provisional application No. 63/734,693, filed on Dec. 16, 2024.

(51) Int. Cl. G06F 3/01; H05K 5/00

(52) U.S. Cl. CPC G06F 3/016; G06F 3/014; H05K 5/0086; H05K 5/0091; G06F 2203/013

(57) ABSTRACT

A referred sensation or neural haptic wearable includes an electrode array for transdermal stimulation of a sensory nerve that itself innervates a body part distal to a worn location of the referred sensation wearable. The transdermal stimulation is configured to induce an electrical current or voltage that evokes a sensory impression at an area innervated by the sensory nerve, not at the stimulated sensory nerve itself. In one implementation, the referred sensation wearable takes a finger ring form factor worn on a proximal phalanx of an index finger. In this configuration, the referred sensation wearable can stimulate a portion of a branch of the median nerve extending through the index finger. Upon stimulation of the median nerve, a user wearing the finger ring may perceive pressure applied to the user's fingertip.

### CROSS REFERENCE TO RELATED APPLICATION

This application is a nonprovisional of, and claims the benefit under 35 U.S.C. § 119 of, U.S. Provisional Patent Application No. 63/734,693, filed on Dec. 16, 2024, and entitled “ADAPTIVE COMPRESSION FIT FOR REFERRED SENSATION WEARABLE” the contents of which is incorporated by reference in its entirety.

### TECHNICAL FIELD

Embodiments described herein relate to systems and methods for providing sensory feedback to a wearer of a wearable device and, in particular, to hand-wearable devices configured for referred electrical stimulation of sensory nerves.

### BACKGROUND

Coarse mechanical feedback provided by a conventional haptic element, such as an eccentrically-weighted motor or a linear actuator, can enhance a virtual reality augmented reality, or general purpose computing experience. As a result, many conventional virtual reality controllers, game controllers, and wearable gaming equipment (e.g., haptic gloves, head mounted displays, haptic body suits) can be designed to incorporate one or more haptic elements.

However, conventional mechanical haptic feedback provided by conventional haptic elements is imprecise and nonspecific, and does not evoke natural sensations. Furthermore, many conventional controls and wearable gaming equipment significantly restrict natural range of motion, are electrically and mechanically complex, and are often expensive to purchase and maintain, difficult to store, and complicated to configure and operate. Further still, many conventional wearable gaming equipment are bulky and visually obtrusive (e.g., haptic gloves, head mounted displays) and may not be suitable to simulate convincing augmented reality experiences.

### BRIEF DESCRIPTION OF THE DRAWINGS

Reference will now be made to representative embodiments illustrated in the accompanying figures. It should be understood that the following descriptions are not intended to limit this disclosure to one included embodiment. To the contrary, the disclosure provided herein is intended to cover alternatives, modifications, and equivalents as may be included within the spirit and scope of the described embodiments, and as defined by the appended claims.

FIG. 1 depicts a referred sensation wearable a housing having an extruded obround shape.

FIG. 2A depicts a referred sensation wearable including an extruded obround enclosure with introduced compliance features to support an adaptive compression fit against a wearer's finger.

FIG. 2B depicts the referred sensation wearable of FIG. 2A along view line A-A.

FIG. 2C depicts the referred sensation wearable of FIG. 2A along view line B-B.

FIG. 3 depicts a referred sensation wearable having introduced compliance features to support an adaptive compression fit against a wearer's finger.

FIG. 4 depicts another referred sensation wearable having introduced compliance features to support an adaptive compression fit against a wearer's finger.

FIG. 5 depicts another referred sensation wearable having introduced compliance features to support an adaptive compression fit against a wearer's finger.

FIG. 6 depicts another referred sensation wearable having introduced compliance features to support an adaptive compression fit against a wearer's finger.

FIG. 7 depicts a referred sensation wearable with introduced compliance features and palmar and dorsal electrodes.

FIG. 8 depicts a referred sensation wearable with introduced compliance features and palmar and dorsal electrodes.

FIG. 9 depicts an exploded view of a referred sensation wearable with introduced compliance features and palmar and dorsal electrodes.

FIG. 10 depicts an exploded view of a referred sensation wearable having a hinged clasp.

FIG. 11A depicts a referred sensation wearable with introduced compliance features.

FIG. 11B depicts the referred sensation wearable of FIG. 11A in an expanded configuration.

FIG. 12 depicts another referred sensation wearable with introduced compliance features.

FIG. 13 depicts another referred sensation wearable with introduced compliance features.

FIG. 14 depicts a cross section of a referred sensation wearable including an extruded obround enclosure with introduced compliance features to support an adaptive compression fit against a wearer's finger.

FIG. 15 depicts a referred sensation wearable including an electrode lead raceway.

FIG. 16A depicts a referred sensation wearable with an extruded obround enclosure.

FIG. 16B depicts a referred sensation wearable with a cylindrical enclosure.

FIG. 16C depicts a referred sensation wearable with a rounded rectangle enclosure.

FIG. 16D depicts a referred sensation wearable with another cylindrical enclosure.

FIG. 16E depicts a referred sensation wearable with a spherical enclosure.

FIG. 16F depicts a referred sensation wearable with an extruded polygonal enclosure.

FIG. 16G depicts a referred sensation wearable with another rectangular enclosure.

FIG. 16H depicts a referred sensation wearable with a partially triangular enclosure.

FIG. 17A a side view of a referred sensation wearable with an elastic strap.

FIG. 17B a side view of a referred sensation wearable with an adjustable strap.

FIG. 17C a side view of a referred sensation wearable with an elastic strap.

FIG. 17D a side view of a referred sensation wearable with a configurable aperture.

FIG. 18A a side view of a referred sensation wearable with an elastic tensioner.

FIG. 18B a side view of a referred sensation wearable with a spring-biased tensioner.

FIG. 18C a side view of a referred sensation wearable with an elastic tensioner.

FIG. 18D a side view of a referred sensation wearable with multiple tensioners.

FIG. 19A a side view of a referred sensation wearable with a pivoting clamp tensioner.

FIG. 19B is a side view of the referred sensation wearable in an open configuration.

FIG. 20A a side view of a referred sensation wearable with an elastic clamp tensioner.

FIG. 20B is a side view of the referred sensation wearable in an open configuration.

FIG. 21A a plan view of a folding circuit board that can clamp around a battery of a referred sensation wearable as described herein.

FIG. 21B depicts the folding circuit board of FIG. 21A in a closed configuration around a battery.

FIG. 21C depicts a rotated view of the folding circuit board of FIG. 21A in a closed configuration around a battery.

FIG. 22 depicts a simplified system diagram of a sensory feedback system, as described herein.

FIG. 23 depicts a simplified system diagram of a referred sensation wearable configured to provide sensory feedback to a wearer.

FIG. 24 is a flowchart depicting example operations of a method of wearing a referred sensation wearable as described herein.

FIG. 25 is a plan view of dorsal and palmar electrode patterns defining optical sensing apertures.

FIG. 26 is a schematic view of an example anode/cathode operational configuration of an electrode pattern as described herein.

FIG. 27 is a schematic view of an example anode/cathode operational configuration of an electrode pattern as described herein.

FIG. 28 is a schematic view of an example anode/cathode operational configuration of an electrode pattern as described herein.

FIG. 29 is a schematic view of an example anode/cathode operational configuration of an electrode pattern as described herein.

FIG. 30 is a schematic view of an example anode/cathode operational configuration of an electrode pattern as described herein.

FIG. 31 is a schematic view of an example anode/cathode operational configuration of an electrode pattern as described herein.

FIGS. 32A-32B depict a neural haptic device as described herein.

FIG. 33 depicts a neural haptic device housing with a resizable housing.

FIG. 34 depicts a neural haptic device with a resizable housing.

The use of the same or similar reference numerals in different figures indicates similar, related, or identical items.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Embodiments described herein relate to methods for providing sensory feedback to a user of an electronic device or computing system. In particular, many embodiments described herein include a referred sensation wearable or accessory that includes an array of electrodes that in many examples are disposed circumscribe a sensory nerve within a first body part that innervates a second body part distal to the first body part. More generally, embodiments described herein reference a neural haptic device configured to provide haptic effects and sensations, referred or otherwise, by afferent stimulation of a nerve structure of a wearer of the device. As used herein, the phrase “referred sensation wearable” may be used interchangeably with the phrase “neural haptic device.” Although many devices referenced herein are configured for referred sensation, this may not be required of all embodiments.

As a result of this construction and relative positioning of the referred sensation wearable and the sensory nerve, application of particular electrical signals (having specific voltages, amplitudes, pulse width, duty cycle, and so on) to particular sets of electrodes of the array can induce an electrical current or potential difference across the sensory nerve so as to locally augment a membrane potential of the nerve, thereby inducing a depolarization mimicking afferent signaling from a distal area that the sensory nerve innervates. More specifically, the induced electrical signal stimulates the sensory nerve in the first body part in substantially the same manner as that same nerve would be stimulated by an afferent signal originating form the second body part.

As a result of this construction, use of the referred sensation wearable can evoke sensory impressions that are perceived to be occurring at a site that is separated from the referred sensation wearable. Embodiments described herein leverage this construction to, among many applications, enhance an experience of operating a electronic device, receive feedback and/or notifications from an electronic device (e.g., a cellular phone, laptop computer, and so on), improve immersion within a virtual reality or augmented reality environment, or provide real-time sensory feedback to an operator of a remote device, such as a robotic arm or prosthetic device.

In a more simple, non-limiting phrasing, embodiments described herein are configured to induce, by application of transdermally-applied electrical signals (or, in some cases in which a stimulating electronic device is implanted, direct stimulation), an action potential at a sensory nerve that results in a sensory impression that is perceived to be occurring in another part of the body. Accordingly, as described herein, the operation of temporarily stimulating one body part to evoke a sensory impression perceived to originate from another body part is referred to as a “transient synesthetic event” or an “inducted transient synesthetic event.” As noted above, as used herein, the terms “synesthesia” and “synesthetic” refer to sensory impressions or evocations generated in one part of the body in response to stimulation of another, different, part of the body. For example, stimulating a proximal phalanx of a finger to evoke a sensation in the distal or middle phalanx of the same finger. In another example, stimulating a superficial nerve in a wrist to evoke a sensation in a palm, a finger, or a nailbed. More broadly, many embodiments described herein reference stimulation of a section of a gross nerve to induce a feeling that is perceived to originate from a mechanoreceptor distal to that gross nerve section.

A sensation evoked by a stimulation as described herein may vary form embodiment to embodiment or stimulation to stimulation. By modifying location, frequency, pulse width, pulse amplitude, current, voltage, and/or other properties of a signal or a combination of signals applied at an electrode of an electrode array as described herein, different sensations can be evoked at different perceived sensory impression sites. As such, as described herein the phrase “sensory impression modality” refers to a type of sensory impression evoked in a user (e.g., a pressure sensation, a paresthesia sensation, a vibration sensation, a temperature change sensation, and so on) whereas the phrase “sensory impression site” refers to a location at which a user perceives a particular sensory impression to be evoked. Similarly, “stimulation site” refers to a site at which stimulation, whether transdermal or direct or a combination thereof) of a particular sensory nerve occurs. For example, in an embodiment, a referred sensation wearable worn on the proximal phalanx of the right index finger can be used to produce a first set of signals (which may vary over time), via an electrode array thereof, to stimulate a branch and/or cross section of the median nerve passing through the proximal phalanx in a manner that evokes a paresthesia sensation in the right index fingertip of the user. In this example, the stimulation site is the proximal phalanx, the sensory impression site is the fingertip (e.g., distal phalanx), and the sensory impression modality is a paresthesia sensation.

In another embodiment, the referred sensation wearable worn on the proximal phalanx of the right index finger can be used to produce a second set of signals, via an electrode array thereof, to stimulate the branch and/or cross section of the median nerve passing through the proximal phalanx in a manner that evokes a temperature change sensation in the right index fingertip of the user. In this example, the stimulation site is once again the proximal phalanx, the sensory impression site is once again the fingertip (e.g., distal phalanx), but in this example, the sensory impression modality is a thermal sensation.

In another embodiment, the referred sensation wearable worn on the proximal phalanx of the right index finger can be used to produce a third set of signals, via an electrode array thereof, to stimulate the branch and/or cross section of the median nerve passing through the proximal phalanx in a manner that evokes a pressure sensation in the right index fingertip of the user. In this example, the stimulation site is once again the proximal phalanx, the sensory impression site is once again the fingertip (e.g., distal phalanx), but in this example, the sensory impression modality is a pressure sensation. In another embodiment, the referred sensation wearable worn on the proximal phalanx of the right index finger can be used to produce a fourth set of signals, via an electrode array thereof, to stimulate the branch and/or cross section of the median nerve passing through the proximal phalanx in a manner that evokes a pressure sensation in the middle phalanx of the index finger of the user. In this example, the stimulation site is once again the proximal phalanx, the sensory impression site is the middle phalanx, and the sensory impression modality is a pressure sensation.

In another embodiment, a referred sensation wearable worn on the wrist of the right arm can be used to produce a sixth set of signals, via an electrode array thereof, to stimulate the branch and/or cross section of the ulnar nerve in a manner that evokes a vibrating sensation in the little finger of the user. In this example, the stimulation site is the user's wrist, the sensory impression site is the little finger of the user, and the sensory impression modality is a vibrating sensation. In some embodiments, a vibrating sensation can be evoked by pulsing a set of signals that otherwise evoke a sense of pressure. Further to these foregoing described embodiments, different sensory impression modalities and sensory impression sites can be simultaneously stimulated in a user. For example, a thermal impression can be multiplexed with a pressure sensation at the same or a different impression site to evoke a combined sensory impression.

In other cases, a sensory impression site can be moved or shifted during stimulation so that a user perceives that the sensory impression modality is moving (e.g., a pressure sensation starting at a user's fingertip and being drawn toward the user's palm).

In yet other examples, different sensory impression modalities and different sensory impression sites can be stimulated in a particular sequence or pattern to induce an overall, high-order tactile effect.

In some further examples, a transcutaneous motor nerve stimulation can be provided alongside a sensory nerve stimulation as described herein so as to both move a user's body while evoking a sensation therein. For example, a flexion or extension can be induced in a finger alongside a pressure sensation at the fingertip. This combination of motor nerve stimulation and sensory nerve stimulation can evoke a sensation of the presence of a physical object touching the user's finger and deflecting the user's finger by an amount. Further, in some embodiments, both direct stimulation and transcutaneous stimulation can be used cooperatively to evoke particular sensory impressions. For example, a sensory nerve stimulating implant can be configured to communicably couple to a referred sensation wearable positioned over the implant (e.g., providing power inductively thereto, in one example) or worn elsewhere. In these constructions, the implanted device and the referred sensation wearable can be cooperatively operated to provide rich feedback (either motor or sensory or combinations thereof) to a user.

More generally and broadly, operation of a referred sensation wearable as described herein to stimulate one body part to evoke a sensory impression perceived to originate from another body part can be described as “recruiting” nerve action from a sensory nerve to induce a “referred stimulation” of nerves that are innervated by the recruited nerve. As one example, a referred sensation wearable as described herein can take a finger ring form factor. One or more concentric rings of electrodes can be defined along an internal, skin-contacting, surface of the finger ring. Upon placing the referred sensation wearable over the proximal phalanx of the index finger or middle finger, at least a portion of the digital nerve (that innervates the fingertip; the median nerve) passes through the center portion of the ring.

More particularly, this example, the median nerve passes through a circumferentially-distributed array of electrodes. By applying particular electrical signals across specifically selected pairs or sets of these electrodes, the median nerve can be stimulated as described above in a manner that causes a wearer of the ring to perceive that a fingertip of the index finger or middle finger is interacting with a physical object. This artificial sensory impression may be perceived by the wearer as a familiar somatosensory experience, such as an experience of pressure, temperature, texture, and so on. In this manner, the referred sensation wearable recruits the median nerve to provide a referred sensation at a fingertip. In another phrasing, in this manner, the referred sensation wearable induces a transient synesthetic event that causes the user to perceive that his or her fingertip is interacting with a physical object.

More generally and broadly, and in a more simple non-limiting phrasing, embodiments described herein relate to electronic devices that induce somatosensory experiences for users of those electronic devices without requiring that any portion of the electronic device physically contact a site at which the somatosensory experience is perceived to originate. For example, in one embodiment, a referred sensation wearable as described herein may be implemented as a wrist-worn cuff with electrode arrays disposed over and/or around superficial nerves innervating the hand (e.g., radial, ulnar, median). By application of particular electrical signals—which are user-specific in many embodiments—to particular sensory nerves, any number of suitable induced synesthetic experiences can be evoked. For example, the referred sensation wearable may induce a first perception of pressure at the palmar side of a user's thumb and may induce a second perception of pressure at the palmar side of the users index finger. This may cause the user to perceive that a physical object is grasped between the thumb and index finger.

In another example, the referred sensation wearable may induce a perception of heat and a perception of pressure at a fingertip of the index finger. This may cause the user to perceive that the user is touching a hot object. In this example, electrical signaling associated with stimulating a recruited nerve to induce the perception of heat may be multiplexed with electrical signaling associated with stimulating the recruited nerve to induce the perception of pressure. In yet other examples, the referred sensation wearable may induce a perception of a rough texture. This may cause the user to perceive that the user is physically touching a rough-textured object.

These foregoing examples are not exhaustive of the sensory experiences that can be induced or otherwise evoked by a referred sensation wearable as described herein. It may be appreciated that by suitably stimulating a recruited nerve, any combination of sensory impressions can be induced. In particular, a modality of sensory impression (e.g., a type of sensation to be simulated) and a site of sensory impression (e.g., a location from which a particular sensation should be perceived to originate can be varied and controlled by modification of stimulation parameters.

It may also be appreciated that a referred sensation wearable as described herein can be used for a number of suitable purposes. For example, a referred sensation wearable can be communicably coupled, either directly or indirectly, to an event stream of a virtual reality environment so that whenever a virtual character controlled by motions of a user of the virtual reality system interacts with a virtual object, the referred sensation wearable can stimulate one or more nerves of the user's hands to evoke a sensation for the user that the user is physically touching and interacting with the virtual object. In such examples, one or more referred sensation wearables can be configured to operate to stimulate sensory nerves in a number of ways to, for example, create sensory impressions of temperature, texture, pressure, and so on. In some cases, sensory impression of weight can be simulated by increasing a sense of pressure on a lower side of an object relative to an upper side of an object.

In other cases, a virtual reality environment can be configured to directly signal a referred sensation wearable as described herein, in much the same manner that conventional virtual reality environments signal conventional haptic or tactile devices. In such examples, an event stream may be transmitted from a computing device associated with the virtual reality environment, the event stream including structured data objects that define one or more physical interactions between a game character and a game object (or other game players). For example, a game character may carry tools or weapons that may have different physical characteristics that can be used to inform one or more haptic responses or inducement of one or more transient synesthetic events. In some cases, haptic feedback or output information can be encoded within an audio or visual stream of data. In some embodiments, a referred sensation wearable as described herein can be configured to parse or otherwise extract an event stream of a game (whether virtual reality, augmented reality or otherwise) in order to infer when one or more transient synesthetic events should be induced for a user. In some cases, evoked sensory impressions can be triggered in response to audio or visual signals directly. For example, a trained machine learning algorithm can determine from a video stream whether a user's virtual hand contacts a virtual object. In response to such a determination, a sensory impression can be evoked as described herein in one or more of the user's fingers. In another example, sound may be used to infer that a sensory impression should be evoked. Many configurations and/or triggers (whether direct, indirect, or implied) to initiate a sensory impression as described herein are possible. In yet other examples, a referred sensation wearable as described herein can be configured to provide sensory experiences unrelated to gaming. For example, in some embodiments, a referred sensation wearable as described herein can be configured to detect sensory input as well as stimulate sensory nerves as described above. In these embodiments, for example, two different referred sensation wearables can be coupled to one another—either directly or indirectly—in order to simulate physical contact over a large distance. For example, family members may be able to effectively experience holding hands at a distance. In other examples, gestures or actions of one user may be recorded and replayed for another user at a later time. For example, a parent, grandparent, or friend may be able to record for a child, grandchild, or friend an affectionate gesture, such as tracing a heart shape over the palm of the recipients hand or squeezing a portion of the recipients hand or tapping in a particular personally meaningful pattern, which may be replayed an reexperienced by the child, grandchild, or friend on demand at a later time-potentially after the parent, grandparent, or friend has passed.

In yet other embodiments, a referred sensation wearable as described herein can be leveraged as a notification device or haptic feedback device. For example, a referred sensation wearable can be configured to communicably couple to a personal electronic device such as a cellular phone. In these constructions, the cellular phone can leverage the referred sensation wearable to notify the user of an event, such as an incoming phone call. In one example, the referred sensation wearable may be configured to cause a perception of light tapping on a dorsal side of the user's hand if the user is receiving a telephone or videoconference call.

In yet other embodiments, a referred sensation wearable can be used to augment an experience of interacting with a physical object. For example, a referred sensation wearable as described herein can impart a feeling of pressing a physical key when a user presses an stationary, flat, touch screen. In other examples, a referred sensation wearable can be configured to assist with direction finding. For example, the referred sensation wearable can be configured to cause the user to perceive a tap on the right hand if the user is meant to turn right and to cause the user to perceive a tap on the left hand if the user is meant to turn left. In another example, direction finding can be provided with thermal sensory experiences. For example, a user may experience a cold sensation in an index finger if the user is oriented in an incorrect direction, whereas the user may experience a warm sensation in the index finger if the user is oriented in a correct direction.

These foregoing example embodiments are not exhaustive of all use cases of the devices, architectures, and systems described herein; it may be appreciated that many configurations and uses are possible. For example, in some cases sensory impressions as described herein can be presented alongside traditional media such as music, motion pictures, art, or live performances. In such cases, different sensory impression modalities and/or different sensory impression sites can be selected to enhance and/or supplement an experience of consuming the traditional media.

For example, a finger ring form factor is merely one example form factor. Other form factors include, but are not limited to: gloves; glovelets; harnesses worn over the hand and including adjustable rings; multi-finger rings; bands over the knuckles connected to rings; wrist-worn devices; implantable devices; sleeve devices; ankle cuff devices; and so on. These form factors may include other components, such as a housing, circuits, batteries, and stimulation boards that are configured to induce a sensory impressions in distal body parts. Generally and broadly, it may be appreciated that a referred sensation wearable as described herein can be suitably configured to couple to any body part over any suitable sensory nerve to induce sensory impressions in other body parts distal thereto (and innervated thereby). In some examples, a referred sensation wearable as described herein can be positioned behind a user's ear to interact with the vestibular system. In these examples, stimulation of sensory nerves can cause disorientation and/or a sense of imbalance. Such embodiments may be used to supplement experiences of viewing a suspense or horror genre motion picture or game. In some examples, such embodiments described herein may also be used to augment proprioception (e.g., in some cases, operated alongside a motor nerve stimulation system to induce particular flexion or extension and/or to prevent or oppose voluntary flexion or extension).

For simplicity of description, many embodiments that follow reference finger-ring form factor referred sensation wearable configured for use with virtual computing environments and in particular to virtual reality environments. However, it is appreciated that this is merely one example implementation; the embodiments described herein can be suitably modified for a number of use cases. Further embodiments described herein relate to field calibration of a referred sensation wearable as described herein. In particular, to determining relative positions of electrodes to relative positions of sensory nerves. In many embodiments, such calibration processes can be facilitated by a portable electronic device such as a cellular phone communicably coupled to a referred sensation wearable as described herein. In these constructions, the referred sensation wearable can be configured to select pairs or sets of electrodes and apply predetermined electrical signals across these electrodes.

The referred sensation wearable can, after a threshold period of time has elapsed, advance to select another pair or set of electrodes to apply the same or a different electrical signal across. While the referred sensation wearable advances through different pairings of electrodes, the portable electronic device can render a graphical user interface that solicits feedback from the user when the user experiences a particular sensory impression modality at a particular sensory impression site. For example, the portable electronic device may render a graphical user interface with a feedback element or affordance that requests the user interact with the affordance upon experiencing a particular sensation.

In this manner, once the user interacts with the affordance, the referred sensation wearable may determine that the most recently-executed signaling properly stimulated the target sensory nerve. With this information, the referred sensation wearable and/or the portable electronic device can create a “calibration profile.” The calibration profile can store information relating which particular electrodes pairs or sets and/or which particular electrical signal properties (e.g., amplitude, frequency, duty cycle, pulse width, and so on) evoked a correct response in the user. The calibration profile may vary from user to user. The calibration profile may also vary each time a user wears the referred sensation wearable, as relative positioning between electrodes and target sensory nerves may change from time to time. As such, in many constructions, the calibration profile may be regularly updated by the user and/or may be requested to be updated regularly by the referred sensation wearable or the portable electronic device. In many cases, the calibration profile is stored in a database or other data store so that the referred sensation wearable can access an appropriate calibration each time the referred sensation wearable is operated to evoke a sensory experience for the user.

In some cases, the referred sensation wearable may also include one or more stimulation profiles including information describing one or more signals that induce particular sensations at particular sites for a particular user. In a more simple phrasing, a simulation profile for a particular modality and a particular site (e.g., a pressure feeling at the tip of the finger) can include information about electrical current or electrical potential required to be induced in or with a particular target sensory nerve. In this manner, a particular simulation profile comprises information describing what particular stimulation should occur to induce a particular sensory effect and a calibration profile comprises information describing how to induce particular signals over or within particular sensory nerves, given a particular user and a particular orientation with which the referred sensation wearable is worn at a particular time. More generally and broadly, by combining information contained in stimulation profiles (as described herein) and calibration profiles (as described herein), a referred sensation wearable as described herein can produce and/or provide any number of sensory experiences for a particular user.

In some embodiments, a referred sensation wearable may be configured as a finger ring defining a finger aperture. An adaptive compression member may define at least a portion of the finger aperture and may be coupled to an obround housing or a housing taking another shape. An elastic element may bias the adaptive compression member toward a contracted configuration.

In other embodiments, an obround housing may be positioned on an upper side of a ring body to encourage a predetermined rotational orientation relative to finger anatomy. The obround housing may retain a controller, a battery, and one or more memory structures associated with stimulation control and profile storage. The battery may be rechargeable (wirelessly and/or conductively), and the controller can include and/or be coupled to one or more communications systems or modules configured to communicably couple to other electronic devices via one or more suitable wireless protocols such as but not limited to Wi-Fi, Bluetooth, Ultrawide Band, Long Range (LoRa) communications, cellular communications, and the like.

In certain implementations, an electrode array may be defined within an interior surface of the adaptive compression member. The electrode array may include a palmar electrode and a dorsal electrode (arranged along a palmar plane and dorsal plane, respectively) or may include at least three electrodes distributed around an interior circumference to support multiple stimulation vectors.

As described herein, electrode structures may be formed from plasticized conductive material, rubberized conductive material, or spring-loaded electrically conductive contacts. Spring-loaded contacts may apply a retaining force against skin to maintain stable electrical contact across flexure of the ring body during finger motion.

In further embodiments, electrode geometries may be arranged as a grid, multiple strips, circular dots, or an arbitrary interlocking pattern. Interdigitated electrode features may be arranged as opposing comb patterns to support spatially selective current paths across adjacent cross sections of a wearer's anatomy.

Further embodiments may include a voltage generating system coupled to the controller and configured to produce stimulation voltages that may be configured to exceed and be conductively or functionally decoupled from or isolated from a system voltage of the controller and battery. Stimulation output ranges may be selected based on comfort thresholds and may be adjusted across a stimulation session and/or between users.

In some embodiments, at least two electrodes of the electrode array may be selected and assigned respective anode and cathode roles to define an electric field positioned to stimulate a sensory nerve innervating a finger. Electrode role assignments may be varied over time to shift a stimulation locus.

In other embodiments, stimulation waveforms may include pulsed signals having variable frequency, amplitude modulation, or duty-cycle modulation. A stimulation sequence may be defined by parameter sets stored in memory and may be selected based on finger identity, ring orientation, or user profile. In some cases, sequences of similar stimulation profiles may vary along a hysteresis curve specific to a user. In other cases, the same evoked stimulation may be physically stimulated in different ways over a period of time. As one example, stimulation may increase in voltage to support the same perceived magnitude of sensory impression if nerves or a user become fatigued over time.

In some embodiments, a calibration procedure may be performed once to generate a user-specific calibration profile. In other embodiments, a calibration procedure may be performed during each wearing session. Calibration data may define electrode pair preferences, pair or set combinations, waveform limits, comfort limits, and timing offsets for multimodal stimulation events.

In certain implementations, stimulation may be configured to evoke referred sensory impressions perceived at a fingertip region or at a selected finger segment. Sensory impression categories may include temperature, wetness, texture, vibration, or pressure. Sensory impression mapping may vary across users and across days.

In additional implementations, wireless communication modules may include Bluetooth, Wi-Fi, or ultra wideband radios for coupling with a host device. Stimulation events may be synchronized with audio or visual outputs for gaming, computing, or notification sequences, including intentional temporal offsets reflecting sensory processing delays.

In an example embodiment, a referred sensation wearable may be wirelessly coupled to an augmented reality headset or a virtual reality headset associated with a host device executing a virtual environment. Event metadata generated by the host device (e.g., corresponding to events occurring between or in respect of objects within the virtual environment) may be transmitted to a controller disposed within a housing of the referred sensation wearable.

In some implementations, a Bluetooth radio, a Wi-Fi radio, or an ultra wideband radio may be disposed within the housing of the referred sensation wearable. A communication session may be established between the referred sensation wearable and the host device to support delivery of a sequences of time-stamped stimulation commands corresponding to and/or supplementing to-be-rendered or currently-rendered virtual object interactions within the virtual environment.

In certain implementations, the controller may be configured to map a time-stamped virtual event to a stimulation profile stored within memory. A user-specific calibration profile may be referenced to select electrode pair assignments, waveform limits, and temporal offsets relative to graphics rendering and audio rendering produced by the headset. In other cases, other calibration profiles may be additionally or alternatively applied, such as those specific to a particular virtual environment, a particular device, a particular virtual reality headset or any combination thereof.

In some implementations, a head-mounted wearable display device and a headphone device may be communicatively coupled to the host device and may also be directly coupled to the referred sensation wearable. Multimodal timing coordination may be established such that a visual event, an audio event, and a sensory impression event are ordered according to stored timing rules.

In additional implementations, a biometric sensor disposed within the referred sensation wearable may provide physiological data to the controller. Physiological data may be transmitted to the host device, and a stimulation profile selection may be adjusted based on a detected state without altering a virtual event schedule defined by the host device.

In some embodiments, multiple referred sensation wearables in ring form factors may be worn on different fingers of a single hand. Coordinated stimulation signals may be applied across electrode arrays of multiple ring bodies to evoke concurrent or otherwise choreographed sensory impressions at multiple fingertips. As an example, a multi-finger grasping event in a virtual environment may be mapped to time-aligned pressure and texture impressions perceived at an index fingertip, a middle fingertip, and a ring fingertip.

In further embodiments, a first referred sensation wearable and a second referred sensation wearable may be operated with different stimulation profiles to evoke distinct sensory impression modalities across different fingers. A sequence of short-duration pressure impressions and brief vibration impressions may be scheduled to correspond to a typing interaction on a planar input surface. An anode/cathode electrode pattern may be selected to vary perceived sensory evocation locations. As with other embodiments, an anode/cathode pattern as described herein can include a single cathode and multiple anodes, a single anode and multiple cathodes, or a single cathode and anode.

As with other embodiments described herein, communication between multiple referred sensation wearables may be supported by direct wireless coupling or by indirect coupling through a host controller. A cellular phone, a laptop computer, a tablet computer, a belt-worn device, or a remote computing device may be used to coordinate stimulation timing and electrode pair assignments. In some cases, stimulation commands may be transmitted over a communication network to support distributed or shared multi-wearer interactions.

In some embodiments, a referred sensation wearable may be configured as a wrist-worn cuff positioned to at least partially circumscribe sensory nerves innervating a hand. An electrode array may be distributed along an inner cuff surface and may be arranged to support selectable stimulation events. Stimulation parameter sets may be mapped to a set of sensory impression sites including a thumb pad region, an index fingertip region, a little fingertip region, a palmar midsection region and the like.

In further embodiments, a wrist-worn cuff may be communicably coupled to a host controller such as a cellular phone, a tablet computer, or a belt-worn device. A stimulation schedule may be generated in response to an event stream associated with a virtual environment or a physical interaction signal. Electrode role assignments may be varied over time to shift an evoked locus across multiple finger segments and across dorsal and palmar surfaces.

As with other embodiments described herein, a wrist-worn cuff may be configured to support multi-modal stimulation across a single hand region. A first waveform set may be selected to evoke a pressure impression at a distal finger region while a second waveform set may be selected to evoke a temperature impression at a thenar region. A time-stamped sequence may be applied to coordinate alternating sensory impression sites associated with a grasping sequence or a typing sequence.

In some embodiments, a referred sensation wearable as described herein may be configured to include one or more sensors and one or more output systems that may be synchronized with an evoked sensory impression. For example, an audio output module may be included within a housing, and an audio chime may be initiated with temporal coordination relative to a pressure sensation, a thermal sensation, or a texture sensation evoked through stimulation of a recruited nerve.

In other embodiments, a referred sensation wearable may be configured to provide a local vibrotactile output while a referred sensory impression is evoked at a distal site. In additional embodiments, a visual indicator such as an LED may be included and may be driven according to a stimulation profile or a calibration profile. In such examples, multiplexed timing rules may be stored in memory for coordinated activation.

In some embodiments, a referred sensation wearable as described herein may be configured to include one or more sensors and one or more output systems that may be synchronized with an evoked sensory impression. For example, an audio output device may be included within a housing, and an audio chime may be initiated with temporal coordination relative to a pressure sensation, a thermal sensation, or a texture sensation evoked through stimulation of a recruited nerve.

In other embodiments, a referred sensation wearable may be configured to provide a local vibrotactile output while a referred sensory impression is evoked at a distal site. In additional embodiments, a visual indicator such as a display or light may be included and may be driven according to a stimulation profile or a calibration profile. In such examples, multiplexed timing rules may be stored in memory for coordinated activation.

It may be appreciated that the foregoing described architectures, including implementations with calibration profiles and stimulation profiles are merely examples; these data items should not be construed as limiting of the manner in which the embodiments described herein can be implemented.

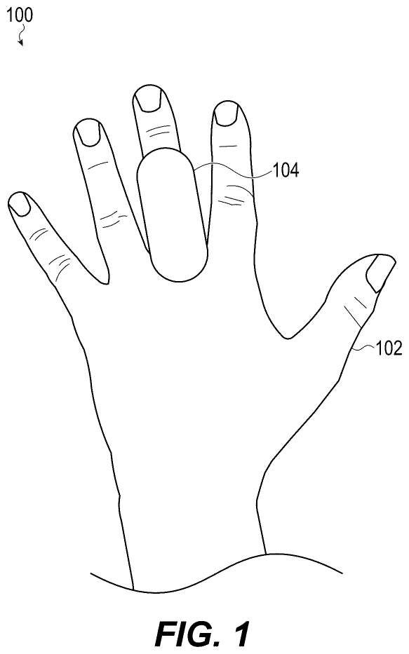

These foregoing and other embodiments are discussed below with reference to FIGS. 1-31. However, those skilled in the art will readily appreciate that the detailed description given herein with respect to these figures is for explanation only and should not be construed as limiting.

FIG. 1 depicts operation of a sensory feedback system, as described herein. The sensory feedback system 100 can, as with other embodiments described herein, leverage one or more referred sensation wearables configured to induce transient synthetic events to provide sensory experiences to a user. The sensory feedback system 100 in this example can include an electronic device, such as a laptop computer or a television. The electronic device can be any suitable electronic device or computing resource; in the illustrated embodiment, the electronic device is not shown but it may be understood in view of an example desktop computing device including a housing that encloses and supports a display configured to render, within an active display area of the display, a graphical user interface.

More specifically, in many embodiments, the electronic device can be implemented as a computing device including a processing resource, a memory resource, communications (e.g., networking) resources, and/or one or more displays and input devices. In such examples, the electronic device can be configured to leverage the processing resource(s) to access one or more executable assets form the memory resource(s) in order to instantiate software configured to render one or more graphical user interface elements in the graphical user interface. For example, the software instantiated by the electronic device may be a virtual reality or gaming environment configured to render one or more three dimensional objects within the graphical user interface. This is merely one example; any suitable user interface can be rendered in the graphical user interface. Other possible devices include virtual reality headsets, augmented reality headsets, pass-through camera mixed reality headsets and heads up displays, holograms, projected visual entertainment systems, mobile platforms, hand-held gaming equipment, and so on. Further, as noted above, in some cases, a wearable device as described herein can be configured to operate with real or traditional physical or virtual media such as artistic paintings/sculptures, live performances, sporting events, and so on.

For embodiments in which the graphical user interface is configured to render a virtual environment, one or more objects may be render and manipulated by a user wearing one or more referred sensation wearables as described herein. For example, in some embodiments, the graphical user interface can be configured to render a three-dimensional object and a three-dimensional object. In the illustrated embodiment, these objects are cubic objects, but it is appreciated that this simplified example is non-limiting.

In this example, a user 102 may interact with the electronic device via motion tracking (not shown; a person of skill in the art may appreciate that many systems for motion tracking may be suitable to track a position of the user and/or a position in space of a body part of the user, such as a left hand or a right hand). In these example, a motion tracking system either incorporated into the electronic device or implemented as a separate electronic device or system can be configured to track position of the right hand and left hand of the user 102. In such examples, motion of the user's hands can be translated by the electronic device into movement of one or both of the one or more objects rendered in the graphical user interface. For example, motion of the right hand may affect a position or orientation in the graphical user interface of a three-dimensional object. Similarly, motion of the left hand may affect a position or orientation in the graphical user interface of the three-dimensional object.

In addition, the user 102 may use one or more referred sensation wearables such as described herein so as to enhance the experience of manipulating three-dimensional objects in the graphical user interface. The referred sensation wearables worn by the user may be configured, as described above, to stimulate a sensory nerve of the user 102 so as to induce or evoke a referred sensation elsewhere in the user's hand or fingers.

For example, the user 102 may wear a referred sensation wearable 104 on a proximal phalanx of the middle finger of the left hand. As a result of this worn position, the referred sensation wearable 104 at least partially circumscribes a cross section (and length) of a portion of the median nerve of the user 102. As known to a person of skill in the art, the median nerve within the middle finger innervates distal portions of the middle finger, including the palmar side of the fingertip (e.g., the index finger pad).

As a result of this construction, the referred sensation wearable 104 can leverage one or more electrodes (configured to operate with appropriate stimulation profiles and calibration profiles, such as described herein) to stimulate the median nerve (the recruited nerve) so as to evoke, in a fingertip, a sensory impression originating at a sensory impression site at the fingertip of the right hand of the user.

In a more simple phrasing, the referred sensation wearable 104, worn on the proximal phalanx of the middle finger, is operated to evoke a sensory impression in the user 102 at the user's fingertip, separated from the referred sensation wearable 104 by a distance. In this manner, the referred sensation wearable 104 induces a transient synesthetic event in the right hand of the user 102.

In some cases the user 102 can wear multiple referred sensation wearables. The referred sensation wearables can be operated in concert with (e.g., synchronized) the software executing on the electronic device such that induced transient synesthetic events in the fingertips of the right hand and the left hand can be provided together with motion-tracked interactions with the three-dimensional objects.

More particularly, as the user 102 moves the index finger of the right hand toward a virtual surface of the three-dimensional object, the motion tracking system may signal the referred sensation wearable 104 to induce a pressure sensation in the index finger of the user's right hand. In this manner, and as a result of this induced sensory impression, the user 102 may perceive that the user is physically touching a virtual surface of the three-dimensional object at a touch location.

Similarly, as the user 102 moves the middle finger of the left hand toward a virtual surface of the three-dimensional object, the motion tracking system may signal the referred sensation wearable to induce a pressure sensation, temperature sensation, texture sensation, or time-varying sensation in the middle finger of the user's left hand. In this manner, and as a result of this induced sensory impression, the user 102 may perceive that the user is physically touching a virtual surface of the three-dimensional object at a touch location.

These foregoing embodiments depicted in FIG. 1 and the various alternatives thereof and variations thereto are presented, generally, for purposes of explanation, and to facilitate an understanding of various configurations and constructions of a sensory impression system or sensory feedback system, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

More specifically, it may be appreciated that a referred sensation wearable as described herein can be co-operated with any suitable electronic device or system of electronic devices to supplement interactions with those electronic devices with sensory impressions. A referred sensation wearable can be operated to, without limitation: enhance a sensory experience of playing a video game; enhance a sensory experience of navigating a virtual reality or augmented realty environment; provide sensory feedback to a surgeon performing a robot-assisted surgery; provide sensory feedback between persons separated by a distance; provide sensory feedback to differently-abled persons, such as guidance feedback to a vision impaired person; provide sensory feedback triggered by an event at an electronic device such as receipt of an incoming call or new message; provide physical feedback to a user of a planar input surface (e.g., simulating button presses or keystrokes); provide sensory feedback to guide a user's finger positions when playing an instrument; provide sensory feedback to a user when operating machinery, such as a motor vehicle; provide sensory feedback to wake a sleeping person; provide sensory feedback to an operator of a prosthetic limb; provide sensory feedback among multiple wearers to cause multiple users to experience similar or identical sensory impressions simultaneously; improve an experience of online or remote shopping, enabling a user to feel or otherwise interact with a product prior to purchase; provide sensory feedback as an authentication mechanism (e.g., a user can identify which finger or body part among many were stimulated); and so on.

In some constructions, a referred sensation wearable as described herein can be configured to induce discomfort, imbalance, or disorientation for entertainment or training purposes. For example, a referred sensation wearable as described herein can be positioned nearby the vestibular system of the user (e.g., behind the user's ear) and may be configured to stimulate the vestibular system to cause a perception of imbalance, nausea, vertigo, or disorientation in the user. In yet other examples, a system as described herein may also be used to assist persons with undesirable involuntary efferent signaling (e.g., tremors and the like). In these examples, a referred sensation wearable may be configured to induce electrical signaling that counteracts unintended or undesirable efferent signaling. In other cases, the referred sensation wearable may be configured to induce electrical signaling that counteracts unintended afferent signaling that, in turn, causes one or more undesirable efferent signals in response.

In further embodiments, virtual objects that can be interacted with by a user can be visually emphasized in some manner, such as with a glow, a particular color, edge blurring or fuzzing, or another visual or audio indication.

These foregoing examples are not exhaustive; a referred sensation wearable as described herein can be configured to operate in a number of suitable ways and may be configured to operate with, and/or in place of, many haptic notification or haptic feedback systems.

In addition, it may be appreciated that a referred sensation wearable can be wirelessly coupled with one or more host devices (phones, computing appliances, gaming devices, controllers). In these examples, the referred sensation wearable can include a housing, a battery, control electronics, stimulation electronics, and the like. In many examples, these electronics are disposed within a housing or enclosure that may take an extruded obround shape, also referred to as a stadium shape extruded along a normal axis by a distance. Such a shape can maximize internal enclosed volume while also enabling natural movement of all fingers by the user 102. In other words, as a result of the shape of the housing, multiple referred sensation wearables can be worn on adjacent fingers without mechanically interfering with one another.

In certain embodiments, additional or alternative configurations are possible. For example the sensory feedback system 100 as described herein may be operated with a user-specific calibration profile and one or more stimulation profiles. The calibration profile may be referenced to determine electrode pair selection, electrode role assignment, and waveform limits for a wearing session. The stimulation profile may be referenced to associate a sensory impression modality and a sensory impression site with a stimulation parameter set for a recruited nerve.

A comfort threshold envelope may be enforced during operation of the referred sensation wearable 104. Stimulation amplitude, duty cycle, pulse width, and frequency may be bounded by stored limits associated with the user 102. Default limits may be applied prior to generation of a calibration profile or a set of calibration profiles. Different calibration profiles may be combined together to provide stimulation for a particular wearer. For example, common biometric features (e.g., hand size), demographics, and the like can be grouped into common calibration profiles that, in turn can be combined to stimulate a particular user. In other cases, a use case or application may itself be associated with a particular calibration—for example, a notification calibration profile may be different from a virtual reality calibration profile.

The sensory impression site may be selected as an index fingertip, a middle fingertip, a ring fingertip, a little fingertip, or a palmar region adjacent to a fingertip. The recruited nerve may be selected as a branch of the median nerve, a branch of the ulnar nerve, or a branch of the radial nerve based on finger identity. Finger identity and hand identity may be varied without altering the operational sequence depicted in FIG. 1.

The motion tracking system referenced in FIG. 1 may be implemented as a headset-based hand tracking system, an external camera system, an inertial sensing system integrated into the referred sensation wearable 104, or a controller-based pose inference system. A position of the right hand and a position of the left hand may be determined from optical tracking, inertial measurements, or sensor-fused outputs. A contact event may be inferred from kinematic thresholds, positional overlap, or from a physics engine.

The electronic device associated with the sensory feedback system 100 may be implemented as a virtual reality headset, an augmented reality headset, a cellular phone, a tablet computer, a laptop computer, a gaming console, or a desktop computing device. The host device may be configured to transmit time-stamped stimulation commands to the referred sensation wearable 104. Timing offsets relative to audio rendering or visual rendering may be stored in memory.

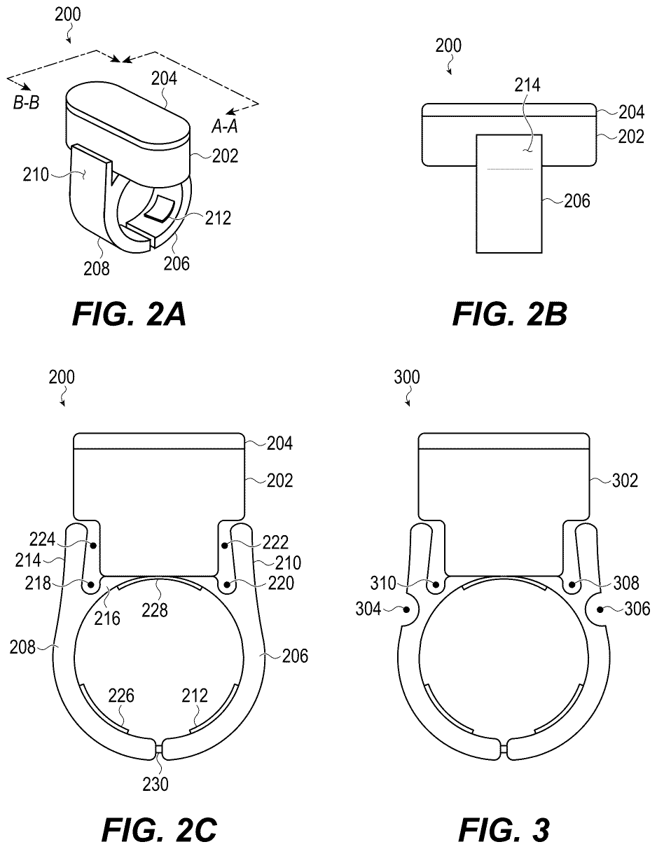

FIGS. 2A-31 each relate to a referred sensation wearable as described herein and, in particular, to structures that facilitate tensioning and/or dynamic compression against a wearer's finger, wrist, or other body part. This compression ensures that electrode contact is maintained. In particular, in these figures:

FIGS. 2A-2C depict a referred sensation wearable including an extruded obround enclosure with introduced compliance features to support an adaptive compression fit against a wearer's finger. In particular, FIGS. 2A-2C depict: a referred sensation wearable 200 with adaptive compression; an obround housing 202; a cap 204; an adaptive compression member part 206; an adaptive compression member part 208; an adaptive compression leverage wing 210; a palmar electrode 212; a second adaptive compression leverage wing 214; a base portion 216; an introduced compliance void 218; an introduced compliance void 220; an adaptive compression recess 222; an adaptive compression recess 224; another palmar electrode 226; a dorsal electrode 228; an elastic band 230. A user can apply pressure to one or both of the compression leverage wings to retract the wings into the recesses and to apply tension to the elastic band 230 to increase a diameter of the adaptive compression parts of the referred sensation wearable 200.

More particularly, a referred sensation wearable 200 is illustrated in FIGS. 2A-2C as a finger-worn device with an adaptive compression architecture or structure as described herein. The referred sensation wearable 200 may include an obround housing 202 (or a housing of another shape) positioned on an upper side of a ring structure that defines a finger aperture into which a finger of a user/wearer may be inserted. A cap 204 may be coupled to the obround housing 202 to enclose internal components and to define an exterior profile shown in FIG. 2A. In some cases, the cap 204 may be made from the same or different materials as the obround housing 202, but this is not required of all embodiments.

An adaptive compression member part 206 may be coupled to a lower region of the obround housing 202. An adaptive compression member part 208 may be positioned opposite the adaptive compression member part 206. The adaptive compression member part 206 and the adaptive compression member part 208 may cooperate to define a finger aperture and to permit expansion prior to and during finger insertion as illustrated across FIGS. 2A-2C.

A first adaptive compression leverage wing 210 may extend adjacent the adaptive compression member part 206 and may be configured to move toward the obround housing 202 under an applied force. A palmar electrode 212 may be disposed along an interior-facing surface of a ring body associated with the adaptive compression member part 206. The palmar electrode 212 may be positioned to contact skin within a palmar plane when the finger aperture is in a contracted configuration.

A second adaptive compression leverage wing 214 may be positioned opposite the first adaptive compression leverage wing 210 and may be configured for coordinated movement with the first adaptive compression leverage wing 210. A base portion 216 may be defined by a lower segment of the ring structure between the adaptive compression member part 206 and the adaptive compression member part 208. The base portion 216 may provide structural support for a finger aperture geometry.

A first introduced compliance void 218 may be defined adjacent the second adaptive compression leverage wing 214. A second introduced compliance void 220 may be defined adjacent the first adaptive compression leverage wing 210. The first introduced compliance void 218 and the second introduced compliance void 220 may be arranged to increase flexibility of the ring structure and to permit controlled deformation during actuation of the first adaptive compression leverage wing 210 and the second adaptive compression leverage wing 214.

A first adaptive compression recess 222 may be defined within a side region of the obround housing 202 adjacent the first adaptive compression leverage wing 210. A second adaptive compression recess 224 may be defined within an opposing side region of the obround housing 202 adjacent the second adaptive compression leverage wing 214. The first adaptive compression recess 222 and the second adaptive compression recess 224 may be sized to receive portions of the first adaptive compression leverage wing 210 and the second adaptive compression leverage wing 214 during compression actuation.

Another palmar electrode 226 may be disposed along an interior-facing surface of the adaptive compression member part 208. A dorsal electrode 228 may be disposed along an interior-facing surface of an upper arc of the ring structure opposite the palmar electrode 212 and the other palmar electrode 226. An elastic band 230 may be coupled across lower regions of the adaptive compression member part 206 and the adaptive compression member part 208 to bias the finger aperture toward a contracted configuration that maintains contact between an electrode array and skin.

FIG. 3 depicts a referred sensation wearable having introduced compliance features to support an adaptive compression fit against a wearer's finger. The referred sensation wearable 300 includes an obround housing 302 with multiple regions of introduced compliance 304, 306, 308, 310, both interior and exterior to a finger aperture defined by the wearable.

A referred sensation wearable 300 is illustrated in FIG. 3 with a housing-forward ring architecture configured for adaptive fit. The referred sensation wearable 300 may be shown in a simplified plan view to emphasize compliance features and a relationship between a housing structure and a finger aperture. The referred sensation wearable 300 may be configured for placement about a wearer finger while maintaining electrode contact as described elsewhere herein.

An obround housing 302 may be positioned on an upper side of the referred sensation wearable 300. The obround housing 302 may be configured to enclose a controller, a battery, and one or more communication modules. The obround housing 302 may be formed as a unitary body or as multiple joined parts with a cap structure not separately illustrated in FIG. 3.

A first introduced compliance region 304 may be formed adjacent a left-side interface between the obround housing 302 and a ring body region. The first introduced compliance region 304 may be configured as a reduced thickness region, a void, or a material transition. The first introduced compliance region 304 may be configured to permit flexure responsive to insertion of a finger into a finger aperture.

A second introduced compliance region 306 may be formed adjacent a right-side interface between the obround housing 302 and a ring body region. The second introduced compliance region 306 may be arranged opposite the first introduced compliance region 304 to support balanced expansion. The second introduced compliance region 306 may be configured to cooperate with the first introduced compliance region 304 during contraction after finger insertion.

A third introduced compliance region 308 may be positioned along an exterior side of the ring body of the referred sensation wearable 300. The third introduced compliance region 308 may be configured to supplement flexure provided by the first introduced compliance region 304 and the second introduced compliance region 306. The third introduced compliance region 308 may be arranged to reduce stiffness at a local segment of the ring body.

A fourth introduced compliance region 310 may be positioned along an opposing exterior side of the ring body of the referred sensation wearable 300. The fourth introduced compliance region 310 may be arranged in symmetry with the third introduced compliance region 308. The fourth introduced compliance region 310 may be configured to support deformation of the ring body while maintaining a target rotational orientation of the obround housing 302 relative to finger anatomy. More particularly, the housing may encourage the user to place the housing along the dorsal side of the hand, to ensure consistent orientation.

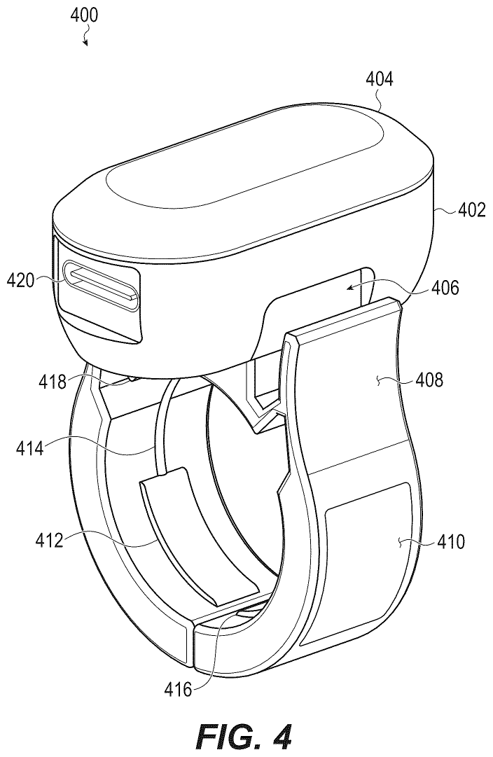

FIG. 4 depicts another referred sensation wearable having introduced compliance features to support an adaptive compression fit against a wearer's finger. The referred sensation wearable 400 includes an obround housing 402 with a cap 404.

The obround housing 402 may be integrally formed with an adaptive compression member configured to define a finger aperture to fit over a wearer's finger. The obround housing 402 defines a recess 406 into which a compression lever 408 can be received when pressed. The referred sensation wearable 400 includes an access panel 410 that can be used for routing wires for electrodes, such as the electrodes 412. Conductors associated with the electrodes 412 can be routed through a raceway 414. The referred sensation wearable 400 can include other electrodes, such as another palmar electrode 416 or a dorsal electrode 418. The referred sensation wearable 400 may be battery operated and charged via charging port 420.

The electrodes 412 may be disposed along an interior-facing surface of the ring body and may be positioned to contact skin within the finger aperture when the referred sensation wearable 400 is worn. The electrodes 412 may be conductively coupled to a controller retained within the obround housing 402. The access panel 410 may be positioned along an exterior region of the ring body to permit access to a portion of the electrodes 412 or to permit access to conductor terminations associated with the electrodes 412.

The raceway 414 may be defined within the ring body and may be configured to route one or more conductors between the electrodes 412 and circuitry disposed within the obround housing 402. The palmar electrode 416 may be disposed along a lower interior region of the ring body and the dorsal electrode 418 may be disposed along an opposing interior region relative to the palmar electrode 416. The charging port 420 may be defined within an exterior wall of the obround housing 402 and may be coupled to a power source retained within the obround housing 402.

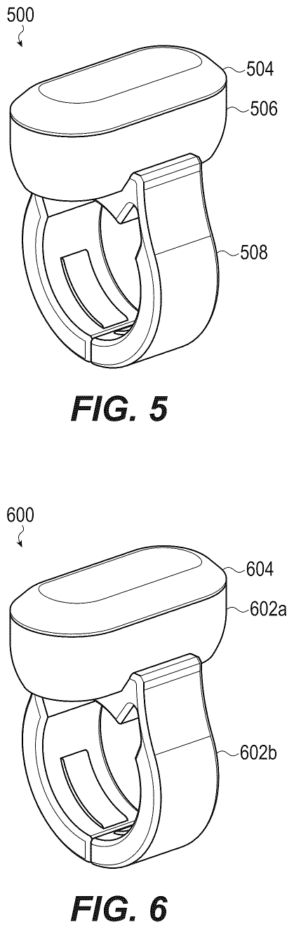

FIG. 5 depicts another referred sensation wearable having introduced compliance features to support an adaptive compression fit against a finger of a wearer. A referred sensation wearable 500 may include an obround housing that may be defined from multiple parts. A cap 504 may be coupled to a housing part 506 to close an enclosure volume. The housing part 506 may be separately formed from, and attached to, an adaptive compression ring part 508. The housing may be formed form plastic, metal, ceramic, glass, or any other suitable metal. In some cases, the obround housing may not be required, and the referred sensation wearable may be entirely ring-shaped.

In some embodiments, the cap 504 may be removably coupled to the housing part 506 by a snap feature, a threaded interface, or a fastener interface. The cap 504 may be formed from a polymer, a metal, or a composite material selected independently from a material of the housing part 506. The housing part 506 may be configured to retain a controller, a battery, and a communication module, while an exterior profile of the cap 504 may be selected to maintain a low interference shape relative to adjacent fingers.

In further embodiments, the adaptive compression ring part 508 may be formed from a flexible polymer or an elastomeric material, and the housing part 506 may be formed from a more rigid polymer or metal. A material transition between the housing part 506 and the adaptive compression ring part 508 may be configured to define an introduced compliance region. A conductor routing passage may be defined across an interface to couple an electrode array disposed within the adaptive compression ring part 508 to circuitry disposed within the housing part 506.

In additional embodiments, a sealing element may be positioned between the cap 504 and the housing part 506. A gasket, an overmolded lip, or a compressible seal may be positioned along a perimeter of the cap 504. The adaptive compression ring part 508 may be configured with a split region, a reduced thickness arc, or one or more cutouts to permit controlled expansion during finger insertion. A mechanical stop feature may be integrated to limit an expansion range of the adaptive compression ring part 508.

In further embodiments, the adaptive compression ring part 508 may be formed from a flexible polymer or an elastomeric material, and the housing part 506 may be formed from a more rigid polymer or metal. A material transition between the housing part 506 and the adaptive compression ring part 508 may be configured to define an introduced compliance region. A conductor routing passage may be defined across an interface to couple an electrode array disposed within the adaptive compression ring part 508 to circuitry disposed within the housing part 506.

FIG. 6 depicts another referred sensation wearable having introduced compliance features to support an adaptive compression fit against a finger of a wearer. The referred sensation wearable 600 includes an obround housing 602 that integrally forms two parts, a housing part 602a and a compression ring part 602b. The obround housing 602 may be formed as a unitary body in which the housing part 602a transitions into the compression ring part 602b without a discrete mechanical joint.

In some embodiments, the housing part 602a may be configured to retain a controller, a battery, and one or more communication modules. The compression ring part 602b may be configured to define a finger aperture and to include one or more introduced compliance regions as described elsewhere herein. A reduced thickness region or a localized cutout may be defined within the compression ring part 602b to permit flexure during finger insertion and removal.

A cap 604 may be coupled to an upper opening of the housing part 602a. The cap 604 may be formed from a material selected independently of a material of the obround housing 602. The cap 604 may be coupled by an adhesive, a weld, a snap interface, or a fastener interface. A sealing element may be positioned between the cap 604 and the housing part 602a to resist ingress of moisture or debris.

In additional embodiments, an interior-facing surface of the compression ring part 602b may be configured to retain an electrode array arranged to contact skin within the finger aperture. A conductor routing passage may be defined within the obround housing 602 to couple the electrode array to circuitry within the housing part 602a. The integrally formed relationship between the housing part 602a and the compression ring part 602b may be selected to support repeatable alignment between a housing orientation and a finger anatomy orientation.

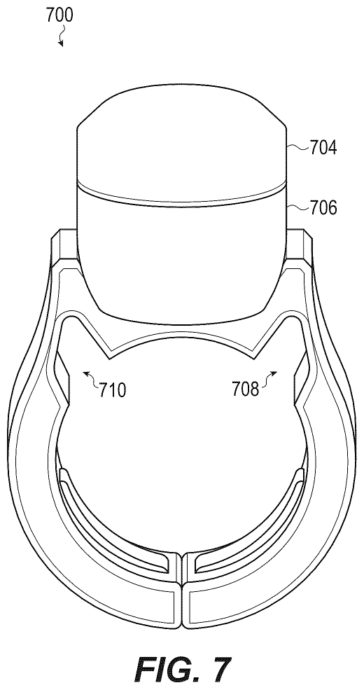

FIG. 7 depicts a referred sensation wearable with introduced compliance features and palmar and dorsal electrodes. A referred sensation wearable 700 includes a cap 704 coupled to a housing 706. The housing 706 may be positioned on an upper side of a ring body and may be configured to retain a controller, a battery, and one or more communication modules. A first interior-facing introduced compliance feature 708 and a second interior-facing introduced compliance feature 710 may be defined adjacent lower side regions of the housing 706 to permit controlled flexure during insertion of a finger into a finger aperture.

In some embodiments, the first interior-facing introduced compliance feature 708 and the second interior-facing introduced compliance feature 710 may be defined as reduced thickness regions, recessed volumes, or localized cutouts extending into the housing 706. The first interior-facing introduced compliance feature 708 and the second interior-facing introduced compliance feature 710 may be arranged to cooperate with an elastic resistance structure disposed within the ring body, although an elastic resistance structure may be omitted in other configurations.

In further embodiments, a palmar electrode and a dorsal electrode may be disposed along an interior-facing surface of the ring body below the housing 706. A conductor routing passage may be defined within the ring body to couple the palmar electrode and the dorsal electrode to circuitry within the housing 706. A rotational orientation feature of the housing 706 may be selected to bias placement of the palmar electrode relative to a palmar anatomical region of a finger.

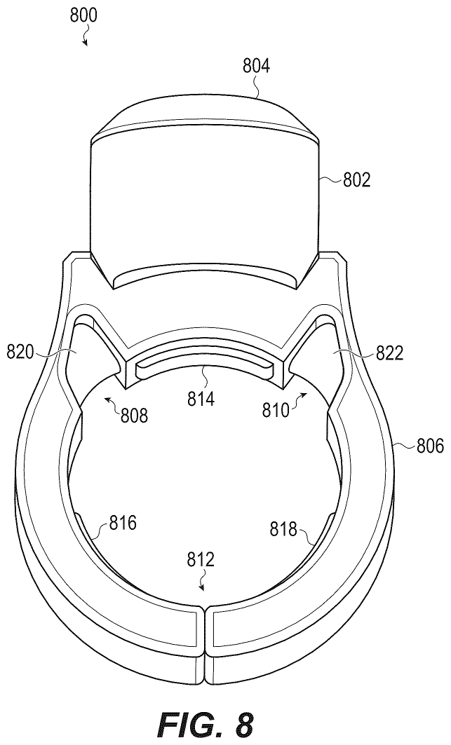

FIG. 8 depicts a referred sensation wearable with introduced compliance features and palmar and dorsal electrodes. The figure illustrates a referred sensation wearable 800. The referred sensation wearable 800 may include a housing 802 positioned on an upper side of a ring body. A housing cap 804 may be coupled to the housing 802 to close an enclosure volume configured to retain internal circuitry.

An adaptive compression member 806 may be coupled to the housing 802 and may be configured to define at least a portion of a finger aperture. An introduced compliance 808 and an introduced compliance 810 may be defined along opposing interior-facing regions of the adaptive compression member 806. The introduced compliance 808 and the introduced compliance 810 may be configured as reduced thickness regions, recessed volumes, or material transitions to permit controlled flexure.

A gap 812 may be defined along a lower region of the adaptive compression member 806 to permit expansion during finger insertion. An electrode 814 may be disposed along an upper interior-facing region of the adaptive compression member 806. An electrode 816 and an electrode 818 may be disposed along lower interior-facing regions arranged to support multiple stimulation vectors relative to a recruited nerve.

An elastic portion and/or flexible raceway 820 may be positioned adjacent a left interior region of the adaptive compression member 806. An elastic portion and/or flexible raceway 822 may be positioned adjacent a right interior region of the adaptive compression member 806. An elastic portion and/or flexible raceway 824 may be positioned along a lower arc to support conductor routing across the gap 812 while permitting repeated expansion and contraction of the adaptive compression member 806.

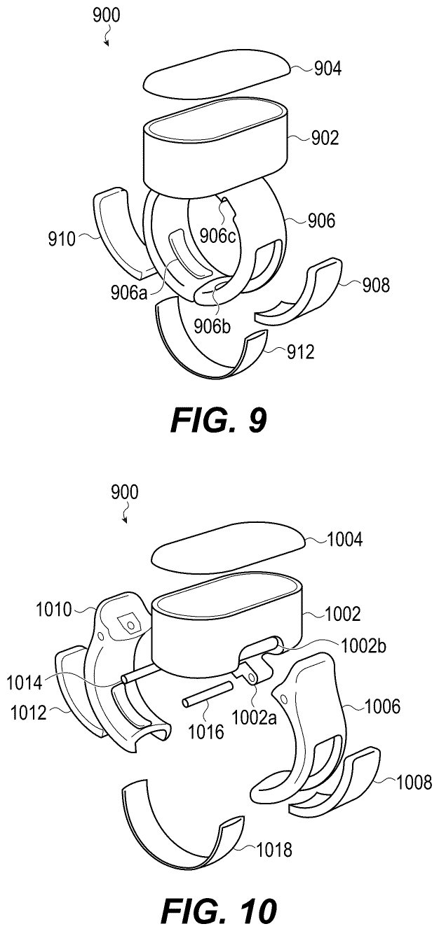

FIG. 9 depicts an exploded view of a referred sensation wearable with introduced compliance features and palmar and dorsal electrodes. The figure illustrates a referred sensation wearable 900 in a disassembled configuration. The referred sensation wearable 900 may include an obround housing 902 positioned to be coupled to an upper region of a ring body. A housing cap 904 may be configured to be coupled to the obround housing 902 to close an enclosure volume configured to retain internal circuitry.

An adaptive compression member 906 may be coupled to the obround housing 902 and may be configured to define at least a portion of a finger aperture. The adaptive compression member 906 may be configured with one or more introduced compliance regions arranged to permit flexure during insertion of a finger and during contraction after insertion. An electrode 906a, an electrode 906b, and an electrode 906c may be disposed along interior-facing surfaces of the adaptive compression member 906 to support multiple stimulation vectors relative to a recruited nerve.

An access door 908 and an access door 910 may be configured to be positioned along opposing exterior regions of the adaptive compression member 906. The access door 908 and the access door 910 may be configured to provide access to conductor routing features or internal cavities of the adaptive compression member 906. An elastic member 912 may be configured to be coupled to lower regions of the adaptive compression member 906 to bias the finger aperture toward a contracted configuration that maintains electrical contact between the electrode 906a, the electrode 906b, and the electrode 906c and skin.

FIG. 10 depicts an exploded view of a referred sensation wearable having a hinged clasp. A referred sensation wearable 1000 is depicted in a disassembled configuration to show a modular ring architecture. The referred sensation wearable 1000 may include an obround housing 1002 configured to be positioned on an upper side of a ring body. A cap 1004 may be coupled to the obround housing 1002 to close an enclosure volume configured to retain internal circuitry.

A pivot bearing 1002a may be defined along a lower side region of the obround housing 1002. A pivot recess 1002b may be defined along an opposing lower side region of the obround housing 1002. An arm 1006 may be positioned to interface with the pivot recess 1002b. A cover/door 1008 may be configured to be coupled to the arm 1006 and may define a portion of a clasped ring arc.

An arm 1010 may be positioned to interface with the pivot bearing 1002a. A cover/door 1012 may be configured to be coupled to the arm 1010 and may define another portion of a clasped ring arc. A pin 1014 and a pin 1016 may be configured to couple the arm 1006 and the arm 1010 to the obround housing 1002 through the pivot bearing 1002a and the pivot recess 1002b. An elastic member 1018 may be coupled to lower regions of the clasp structure to bias a finger aperture toward a closed configuration after a hinged opening operation.

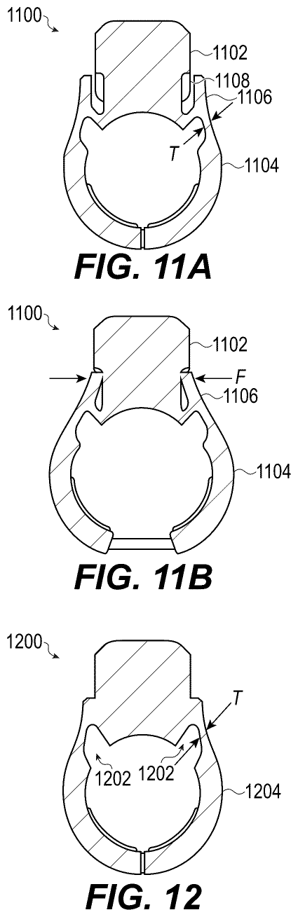

FIG. 11A depicts a referred sensation wearable with introduced compliance features and FIG. 11B depicts the referred sensation wearable of FIG. 11A in an expanded configuration. A referred sensation wearable 1100 may include a housing 1102 coupled to an adaptive compression ring 1104. The adaptive compression ring 1104 may define a finger aperture and may be configured to bias toward a contracted configuration during wearing.

An introduced thinness T may be defined within a portion of the adaptive compression ring 1104 adjacent the housing 1102. The introduced thinness T may be configured to reduce a local stiffness of the adaptive compression ring 1104. The introduced thinness T may be defined as a reduced wall thickness region, a material transition region, or a combination of reduced thickness and localized cutouts.

A compression lever 1106 may be positioned adjacent the introduced thinness T. A recess 1108 may be defined within the housing 1102 and may be configured to receive the compression lever 1106. In response to an application of a force F against the compression lever 1106, the compression lever 1106 may be received within the recess 1108 to cause the adaptive compression ring 1104 to expand by a distance resisted by an elastic member, as described elsewhere herein.

In other cases, leverage may not be required, and a housing may be flexible but of unitary construction.

FIG. 12 depicts another referred sensation wearable with introduced compliance features. A referred sensation wearable 1200 may be illustrated in a cross-sectional view to emphasize deformation regions adjacent an upper housing structure. The referred sensation wearable 1200 may be configured to define a finger aperture with a ring body portion shown in the figure. The introduced compliance regions 1202 may be positioned along opposing interior-facing sides of the ring body.

In some embodiments, the introduced compliance regions 1202 may be defined as reduced thickness regions associated with an introduced thinness T, recessed volumes, or localized cutouts. A ring body 1204 may be configured to cooperate with the introduced compliance regions 1202 to permit expansion during insertion of a finger and contraction after insertion. The introduced compliance regions 1202 may be arranged to maintain stable electrode contact during flexure as described elsewhere herein.

Introduced compliance can be within or exterior to a finger aperture.

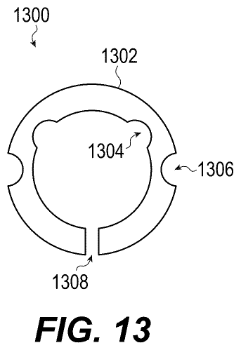

FIG. 13 depicts another referred sensation wearable with introduced compliance features. The figure illustrates a ring 1300 with a body 1302 that has introduced compliance cutouts 1304, 1306 and a keyhole 1308 that facilitates expansion and compression. The body 1302 may be formed from a flexible polymer, an elastomer, or a composite material. The introduced compliance cutouts 1304, 1306 and the keyhole 1308 may be arranged to define localized bending regions along a circumference of the ring 1300.

In some embodiments, a ring-shaped housing may be defined by the body 1302 and may be configured to retain a controller, a battery, and one or more communications systems. In additional embodiments, a voltage generating system may be coupled to the controller and may be configured to produce stimulation voltages for delivery to an electrode array disposed along an interior-facing surface of the body 1302. A conductor routing passage may be defined within the body 1302 to couple the electrode array to circuitry retained within the ring-shaped housing.

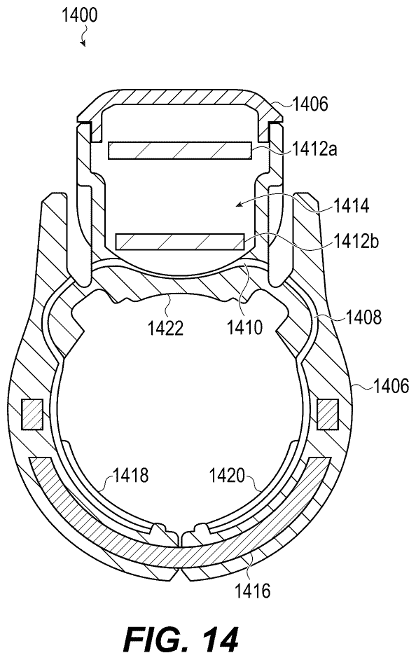

FIG. 14 depicts a cross section of a referred sensation wearable 1400 including an extruded obround enclosure (an obround enclosure having a thickness through which geometry is substantially consistent; “extruded” as used herein may be used to refer to geometry rather than a particular manufacturing process) with introduced compliance features to support an adaptive compression fit against a finger of a wearer.

The referred sensation wearable 1400 may include a housing 1402. A leverage wing 1404 may be positioned adjacent the housing 1402. An arm 1406 may be coupled between the leverage wing 1404 and a ring body region to transmit an applied force associated with expansion of a finger aperture.

A raceway 1408 and a lower raceway 1410 may be defined within portions of the ring body and the housing 1402. The raceway 1408 and the lower raceway 1410 may be configured to route one or more conductors between internal circuitry and one or more electrodes. An upper circuit board 1412a may be positioned within an upper region of the housing 1402. A battery 1414 may be positioned adjacent the upper circuit board 1412a.

A lower circuit board 1414b may be positioned within a lower region of the housing 1402.

In some embodiments, the upper circuit board 1412a and the lower circuit board 1414b may be configured as discrete circuit assemblies electrically coupled by one or more jumpers, one or more flexible cables, or one or more board-to-board connectors. In additional embodiments, the upper circuit board 1412a, the lower circuit board 1414b, or a combined assembly of the upper circuit board 1412a and the lower circuit board 1414b may be implemented as a flexible circuit board folded to define separated mounting regions. The battery 1414 may be configured as a rechargeable battery supporting wireless charging, conductive charging, or a combination of wireless charging and conductive charging.

An elastic resistance band 1416 may be coupled to a lower portion of the ring body to bias a contracted configuration. An electrode 1418 and an electrode 1420 may be disposed along an interior-facing surface of the ring body to provide a palmar-side stimulation structure. An electrode 1422 may be disposed along another interior-facing surface to provide an additional stimulation vector relative to a recruited nerve. The electrode 1418, the electrode 1420, and the electrode 1422 may be conductively coupled to circuitry associated with the upper circuit board 1412a and the lower circuit board 1414b through the raceway 1408 and the lower raceway 1410.

FIG. 15 depicts a referred sensation wearable including an electrode lead raceway. A referred sensation wearable 1500 includes a body portion 1502 that defines a raceway 1504. The body portion 1502 may form at least a portion of a ring body configured to define a finger aperture. The raceway 1504 may be defined as an elongated channel extending along an interior-facing surface of the body portion 1502.

In some embodiments, the raceway 1504 may be configured to receive one or more electrode leads that couple an electrode array positioned within the finger aperture to control electronics retained within a housing of the referred sensation wearable 1500. The raceway 1504 may be open, partially covered, or fully enclosed, and may be shaped to maintain positional stability of the electrode leads during expansion and contraction of the body portion 1502.

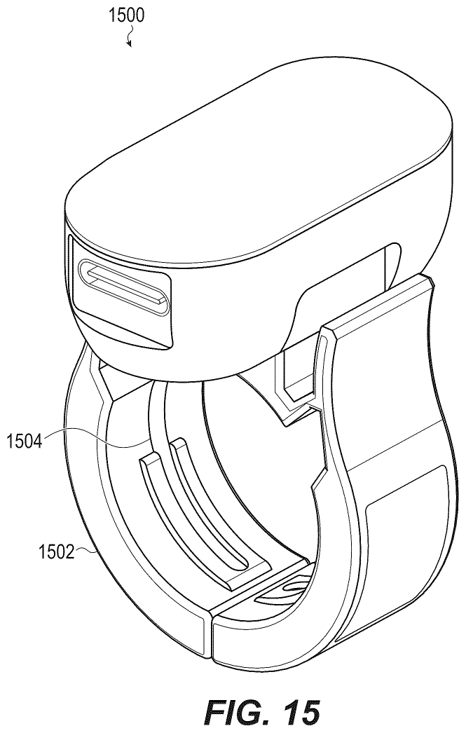

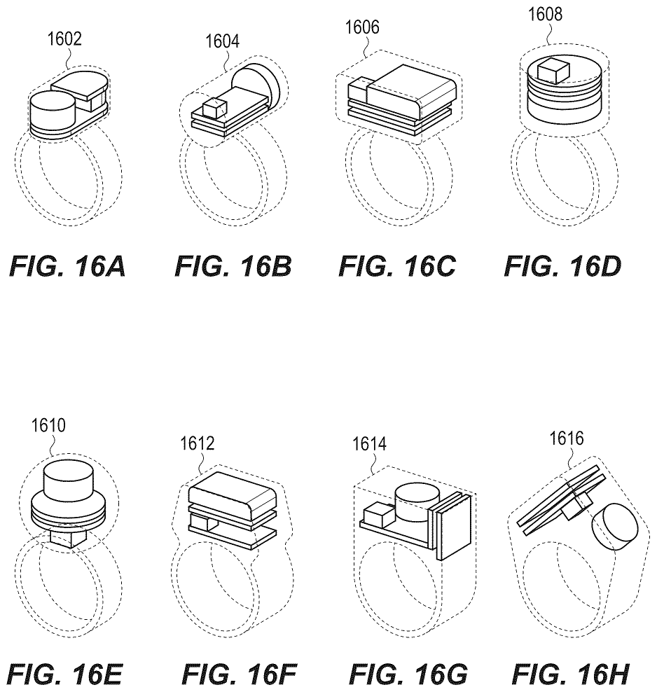

FIG. 16A depicts a referred sensation wearable with an extruded obround enclosure 1602. Within the extruded obround enclosure 1602, an upper circuit board and a lower circuit board may be positioned as stacked planar assemblies aligned with a long axis of the extruded obround enclosure 1602. A battery may be positioned between the upper circuit board and the lower circuit board or may be positioned beneath a primary board plane. A flexible jumper may couple board regions.

FIG. 16B depicts a referred sensation wearable with a cylindrical enclosure 1604. Within the cylindrical enclosure 1604, an annular circuit board or a curved flexible circuit board may be positioned to follow an interior circumference. A battery may be configured as a cylindrical cell positioned coaxially with the cylindrical enclosure 1604 or as a segmented cell arranged around a central void. A controller and a voltage generating system may be positioned on a radial board segment.

FIG. 16C depicts a referred sensation wearable with a rounded rectangle enclosure 1606. Within the rounded rectangle enclosure 1606, a primary circuit board may be positioned as a planar substrate spanning a major face. A secondary circuit board may be positioned perpendicular to the primary circuit board through a board-to-board connector. A battery may be configured as a prismatic cell positioned adjacent the primary circuit board. A flex section may be routed around an interior corner radius.

FIG. 16D depicts a referred sensation wearable with another cylindrical enclosure 1608. Within the cylindrical enclosure 1608, a stacked board architecture may be arranged along an axial direction with a first board plane above a second board plane. A battery may be positioned as a thin cylindrical cell beneath a lower board plane or as a ring-shaped cell surrounding an interior post. A charging interface may be positioned adjacent an exterior wall of the cylindrical enclosure 1608.

FIG. 16E depicts a referred sensation wearable with a spherical enclosure 1610. Within the spherical enclosure 1610, a flexible circuit board may be configured as a partially wrapped band adhered to an interior surface. A battery may be configured as a compact coin cell or as a curved prismatic cell positioned adjacent a central support frame. A controller may be mounted on a rigid island of the flexible circuit board with jumpers extending to peripheral components.

FIG. 16F depicts a referred sensation wearable with an extruded polygonal enclosure 1612. Within the extruded polygonal enclosure 1612, multiple planar circuit board facets may be positioned to align with interior polygon faces. A battery may be configured as a prismatic cell occupying a central cavity with board facets arranged around the prismatic cell. A voltage generating system may be positioned on a dedicated facet to isolate higher-voltage routing from sensor routing.

FIG. 16G depicts a referred sensation wearable with another rectangular enclosure 1614. Within the rectangular enclosure 1614, a primary circuit board may be positioned parallel to a top surface. A secondary circuit board may be positioned along a side wall to support antenna placement or connector placement. A battery may be configured as a flat prismatic cell positioned beneath the primary circuit board with a spacer layer to maintain separation. A flex cable may couple the primary circuit board to the secondary circuit board.

FIG. 16H depicts a referred sensation wearable with a partially triangular enclosure 1616. Within the partially triangular enclosure 1616, a stepped circuit board arrangement may be positioned to follow a tapered internal cross-section. A battery may be configured as a wedge-like prismatic cell or as a segmented cell distributed across a lower volume. A controller may be positioned near a wider upper region while a charging coil or charging contact may be positioned near a broader exterior face of the partially triangular enclosure 1616.

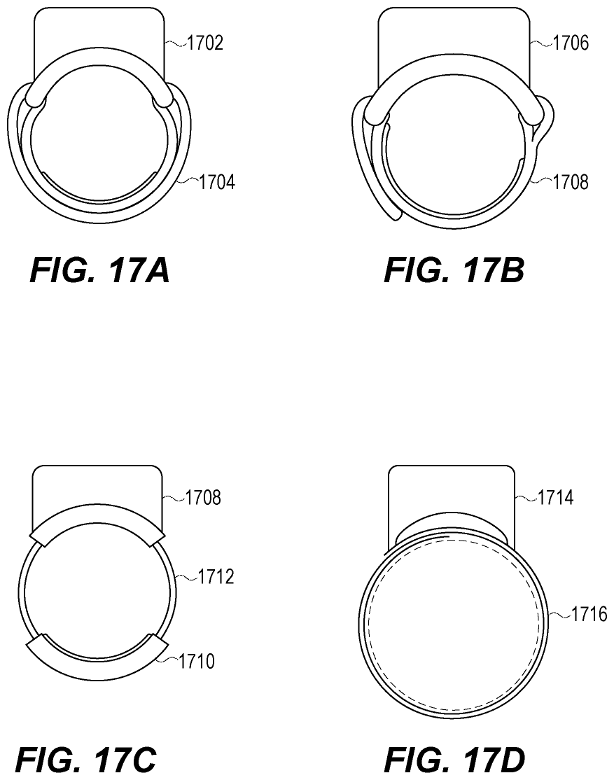

FIG. 17A depicts a side view of a referred sensation wearable 1702 with an elastic strap 1704. The referred sensation wearable 1702 may be configured with a housing portion positioned above a ring body region. The elastic strap 1704 may be coupled to opposing sides of the ring body region to apply a radially inward bias. The elastic strap 1704 may be configured to maintain electrode contact during finger motion.

FIG. 17B depicts a side view of a referred sensation wearable 1706 with an adjustable strap 1708. The referred sensation wearable 1706 may be configured to define a finger aperture with a variable circumference. The adjustable strap 1708 may be configured with a buckle feature, a ratchet feature, a hook-and-loop interface, or a segmented detent structure. The adjustable strap 1708 may permit adjustment of compression to accommodate different finger sizes.

FIG. 17C depicts a side view of a referred sensation wearable 1708 with a rigid ring section 1710 and an elastic strap 1712. The referred sensation wearable 1708 may be configured with the rigid ring section 1710 positioned to support a fixed electrode alignment region. The elastic strap 1712 may be coupled to the rigid ring section 1710 to permit controlled expansion during finger insertion. The elastic strap 1712 may apply a restoring force to bias a contracted configuration.

FIG. 17D depicts a side view of a referred sensation wearable 1714 with a configurable aperture associated with a coiled spring member 1716. The referred sensation wearable 1714 may be configured with the coiled spring member 1716 positioned within or adjacent a ring body region. The coiled spring member 1716 may be configured to provide a distributed radial bias. The coiled spring member 1716 may be configured to maintain compression across a range of finger diameters.

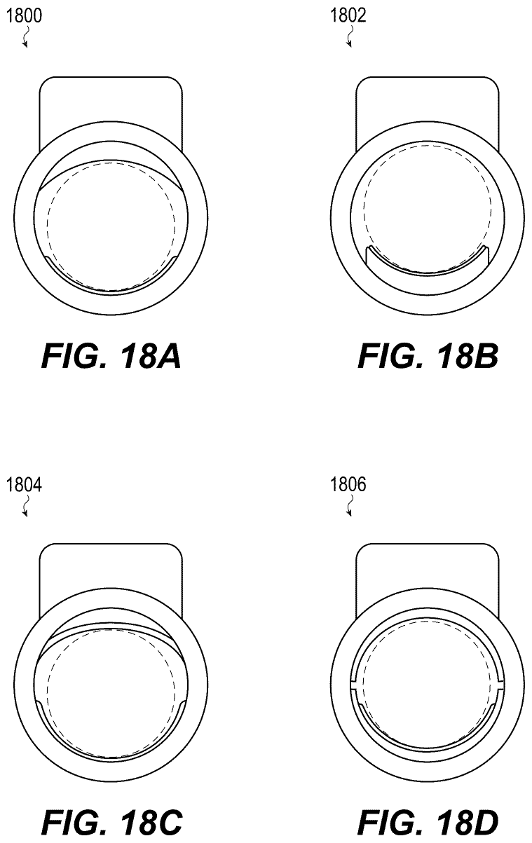

FIG. 18A depicts a side view of a referred sensation wearable 1800 with an elastic tensioner. The referred sensation wearable 1800 may be configured with a housing portion positioned above a ring body region defining a finger aperture. The elastic tensioner may be positioned along an interior circumference or an exterior circumference of the ring body region. The elastic tensioner may be coupled to opposing ring segments to bias a contracted configuration.

FIG. 18B depicts a side view of a referred sensation wearable 1802 with a spring-biased tensioner. The referred sensation wearable 1802 may be configured with a spring element positioned adjacent a lower arc of a ring body. The spring-biased tensioner may be configured as a leaf spring, a curved band, or a segmented spring insert. The spring-biased tensioner may be configured to provide a consistent radial bias across repeated expansion cycles.

FIG. 18C depicts a side view of a referred sensation wearable 1804 with an elastic tensioner. The referred sensation wearable 1804 may be configured with the elastic tensioner positioned as a partial band spanning a localized region of a ring body. The elastic tensioner may be coupled to an introduced compliance feature to concentrate deformation within a selected arc. The elastic tensioner may be configured to permit expansion during finger insertion while preserving a target electrode alignment region.

FIG. 18D depicts a side view of a referred sensation wearable 1806 with multiple tensioners. The referred sensation wearable 1806 may be configured with a first tensioner and a second tensioner positioned at different angular locations around a finger aperture. The multiple tensioners may be configured as combinations of elastic elements and spring elements. The multiple tensioners may be arranged to support asymmetric compression patterns relative to a palmar region and a dorsal region.

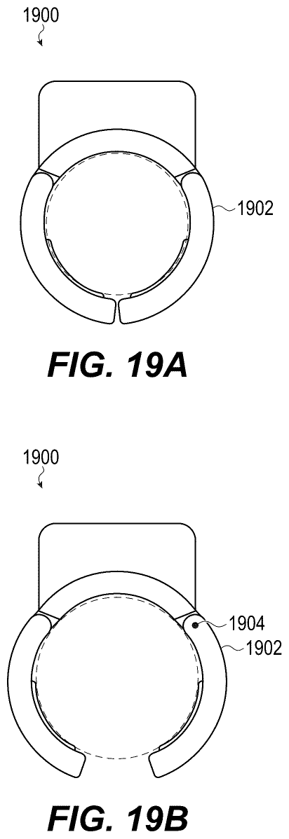

FIG. 19A depicts a side view of a referred sensation wearable 1900 with a pivoting clamp tensioner 1902. The referred sensation wearable 1900 may be configured with a housing portion positioned above a ring body defining a finger aperture. The pivoting clamp tensioner 1902 may be positioned along a lateral region of the ring body and may be configured to apply a compressive force across a local arc.

FIG. 19B depicts a side view of the referred sensation wearable 1900 in an open configuration pivoting about a pivot point 1904. The pivot point 1904 may be positioned adjacent an upper lateral region of the ring body near the housing portion. The pivoting clamp tensioner 1902 may be configured to swing outward to increase a dimension of the finger aperture during finger insertion. The pivoting clamp tensioner 1902 may be configured to return toward a closed position to maintain electrode contact after finger insertion.

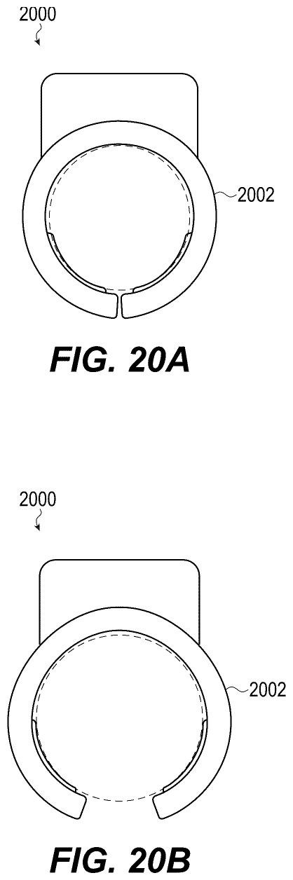

FIG. 20A depicts a side view of a referred sensation wearable 2000 with an elastic clamp tensioner 2002. The referred sensation wearable 2000 may be configured with a housing portion positioned above a ring body defining a finger aperture. The elastic clamp tensioner 2002 may be positioned along a lateral region of the ring body and may be configured as a resilient band, an elastomeric arm, or a compliant strap integrated with a ring body segment.

FIG. 20B depicts a side view of the referred sensation wearable 2000 in an open configuration. The elastic clamp tensioner 2002 may be configured to deform outward to increase a dimension of the finger aperture during finger insertion. The elastic clamp tensioner 2002 may be configured to provide a restoring force that returns the ring body toward a contracted configuration after finger insertion to maintain electrical contact between an electrode array and skin.

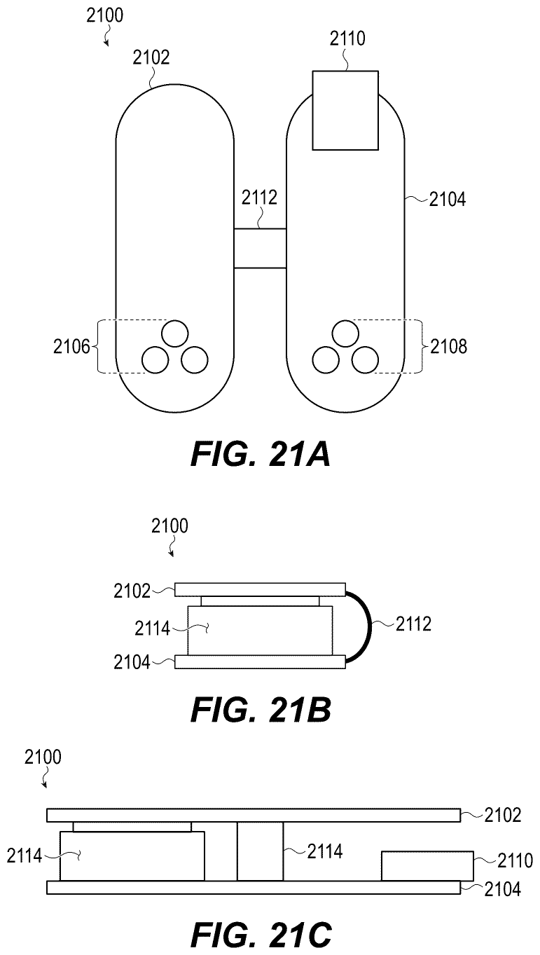

FIGS. 21A-21C depict a plan view and related views of a folding circuit board assembly associated with a battery architecture of a referred sensation wearable as described herein. A board 2100 may include a first board 2102 and a second board 2104. The first board 2102 and the second board 2104 may be configured to bend around a flex 2112. A first set of electrodes 2106 may be disposed on the first board 2102 and a second set of electrodes 2108 may be disposed on the second board 2104.

In the illustrated configuration, the first set of electrodes 2106 may be positioned to engage a first surface of a cylindrical rechargeable battery 2114, and the second set of electrodes 2108 may be positioned to engage a second surface of the cylindrical rechargeable battery 2114 or a second battery of a series battery stack. A port 2110 may be positioned on the second board 2104 axially opposite the cylindrical rechargeable battery 2114 to support mass distribution within a housing of a ring form factor.

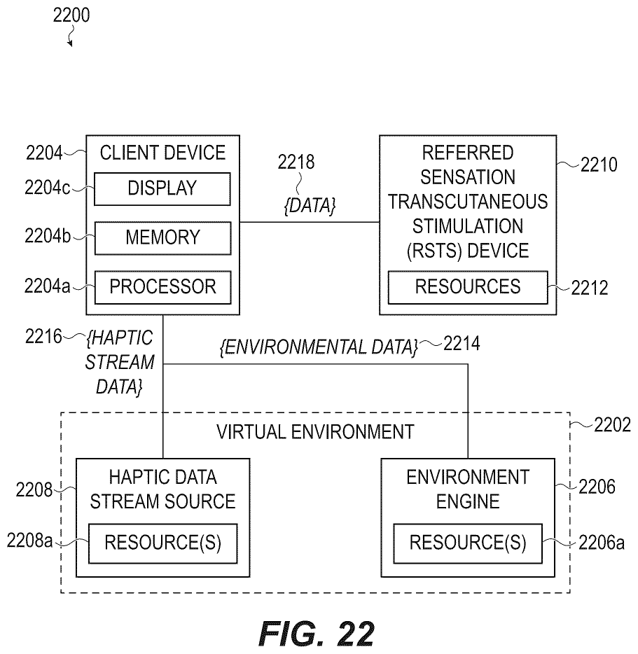

FIG. 22 depicts a simplified system diagram of a sensory feedback system or a sensory impression system, as described herein. The system 2200 operates by cooperation of a referred sensation wearable, a personal electronic device of a user, and a virtual computing/gaming environment. Specifically, the system 2200 includes a virtual environment 2202 communicably coupled to a client device 2204. The virtual environment 2202 can be defined at least in part by an environment engine 2206 (also referred to in some cases as a physics engine or game engine) and a haptic data stream source 2208.

The client device 2204—which may or may not be a referred sensation wearable—is in turn communicably coupled to a referred sensation wearable configured evoke/induce referred sensation by transcutaneous stimulation of a sensory nerve, as described herein. For simplicity of description, the embodiments that follow reference a configuration in which the client device 2204 is a non-referred sensation wearable such as a cellular phone configured to communicate wirelessly or over a wired connection with a referred sensation wearable. For further simplicity of description, a wearable or implantable device (or combination system including at least one wearable device and at least one implantable device) as described herein configured to evoke a referred sensation by transcutaneous or direct stimulation is referred to as a “RSTS” device. In the illustrated embodiment, the client device 2204 is communicably coupled to an RSTS device 2210 that includes, as with other embodiments described herein, an electrode array, processing resources, memory resources, and so on so as to induce sensory impressions by stimulating a recruited nerve, such as the median nerve of a user's hand. Collectively, these resources are identified in the figure as the resources 2212.

The system 2200 may be a gaming system configured to present a virtual reality environment, an augmented reality environment, or a two-dimensionally rendered virtual environment (e.g., metaverse, gaming universe, and so on). In particular, game action can be computed by the environment engine 2206 in response to one or more inputs provided by the client device 2204, which may be communicably coupled to one or more input appliances such as game controllers or motion tracking systems. As game content is updated or computed by the environment engine 2206, information describing the environment can be transmitted to the client device 2204 as environment information 2214. The client device 2204 can consume the environment information 2214 to update a graphical user interface, a rendered game environment, and so on.

In certain circumstances, the environment engine 2206 may determine that a game character interacts physically with an object or other game character rendered in the same environment. For example a game character may grasp a tool or weapon, may operate virtual machinery, or the like. In response to such an event, the environment engine 2206 can signal the haptic data stream source 2208 to generate one or more haptic signals 2216 to the client device 2204. In response, the client device 2204 can provide one or more haptic outputs to a user of the client device including, but not limited to, sensory impressions. More specifically, the client device 2204 can be configured to signal the RSTS device 2210, in response to receiving the haptic signals 2216, with a sensory impression signal 2218.

In a more simple and non-limiting phrasing, the system 2200 can be configured to translate haptic signaling transmitted with, or separate from, game information generated by a game engine into sensory feedbacks that can be perceived by a wearer of an RSTS device, as described herein. For example, a game environment may include one or more virtual objects. As a game character grasps the objects in the virtual environment, a haptic signal may be generated and transmitted to the client device 2204. In a conventional game environment, the haptic signals may cause vibrotactile feedback to be generated in response (e.g., a game controller may vibrate to indicate that the game character has successfully interacted with a virtual object). By contrast, for embodiments described herein, the client device 2204 may convert haptic signaling received from the game environment (e.g., the virtual environment 2202) into sensory signaling that, when received by the RSTS device 2210, can cause a wearer to experience a more genuine sensory experience. For example, in response to a game character grasping an object, a sensory impression of pressure can be induced in each of the user's ten fingertips, evoking an impression that the user his or herself is physically grasping the virtual object.

In these examples, the client device 2204 can be configured to leverage structured information in the haptic signals 2216 to select one or more sensory impression modalities and one or more sensory impression sites. For example, a haptic signal 2216 can be structured data in a JSON format such as:

```
{
  “event_id” : 7f61e0f4-b475-4563-9ed9-95eb7e546e73,
  “timestamp” : “July 19, 2019, 21:44.365478 UTC”
  “hand_right: {
    “index_tip” : “0.5g”,
    “middle_tip” : “0.2g”,
    “ring_tip” : “0.2g”,
    “little_tip” : “0.2g”
  },
  “hand_left: {
    “index_tip” : “0g”,
    “middle_tip” : “0g”,
    “ring_tip” : “0g”,
    “little_tip” : “0g”
  }
```

In this example, the haptic event may correspond to a game character lightly grasping an object with the character's right hand. In particular, this example event, a sensory impression of sub-gram pressures are instructed to be evoked at each fingertip of the right hand, but no pressure events are instructed to be evoked in the left hand.

In other examples, more detailed sensory information can be provided within the haptic signals 2216. For example:

```
{
  “event_id” : d0dfd5ad-926b-4483-b679-1b2c6a0ff689,
  “timestamp” : “July 19, 2019, 21:44.5566879 UTC”
  “hand_right: {
    “index” : {
      “phalanx_proximal” : {[
        “modality” : “pressure”,
        “value” : “0.5g”,
        “duration” : “0.2s”
      },
      {
        “modality” : “temperature”,
        “value” : “-3deg”,
        “duration” : “0.2s”
      }],
      “phalanx_medial” : {[
        “modality” : “pressure”,
        “value” : “0.2g”,
        “duration” : “0.2s”
      },
      {
        “modality” : “temperature”,
        “value” : “-3deg”,
        “duration” : “0.2s”
      }],
      “phalanx_distal” : {[
        “modality” : “pressure”,
        “value” : “2g”,
        “duration” : “0.2s”
      },
      {
        “modality” : “temperature”,
        “value” : “-3deg”,
        “duration” : “0.2s”
      }]
    }
  }
}
```

In this example, the haptic event may correspond to a game character pulling a trigger of a weapon with the index finger of the right hand. In this example, pressure may be felt along the entire palmar side of the right index finger, in addition to a lower temperature (a perceived temperature delta of negative three degrees), which may simulate the feeling of grasping metal.

These foregoing embodiments depicted in FIG. 22 and the various alternatives thereof and variations thereto are presented, generally, for purposes of explanation, and to facilitate an understanding of various configurations and constructions of a sensory impression system or sensory feedback system, such as described herein, when used with a gaming environment to enrich a gaming experience. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, it may be appreciated that the client device 2204 and the virtual environment 2202 can each be embodied in a number of ways. In particular the client device 2204 may be a computing device such as a laptop, gaming console, desktop computing device, and the like. In many constructions, the client device 2204 is configured to instantiate software that in turn is configured to interface with both the RSTS device 2210 and the virtual environment 2202. For example, as with other embodiments described herein, the client device 2204 can include a processing resource 2204a and a memory resource 2204b configured to cooperate to instantiate an instance of software- or more than one instance of software-configured to interface with and/or leverage one or more API endpoints of the virtual environment 2202 and the RSTS device 2210.

The client device 2204 can also include one or more output systems such as displays, haptic elements, speakers, and the like collectively identified as the output resources 2204c. In some examples, a display of the output resources 2204c can be configured to render a graphical user interface that renders at least a portion of a gaming environment defined by the environment engine 2206. The display may be a flat display, a curved display, a projected display, a head mounted display, or any other suitable display. The output resources 2204c can also include one or more haptic output systems such as vibrotactile actuators. These traditional haptic outputs can be provided in concert with outputs provided by the RSTS device 2210.

The output resources 2204c can also include one or more audio output devices configured provide audio generated by or in virtual environments defined by the environment engine 2206. In some embodiments, audio signals and/or visual signals in the environment information 2214 can be provided in sync with the haptic signals 2216. In other words, sounds and sights that accompany a particular haptic effect can be rendered or otherwise produced for the user at the same time. In other embodiments, haptic outputs can be provided in advance of corresponding audiovisual outputs. For example, a sensory impression provided by the RSTS device can lead a corresponding audiovisual effect by a short period, such as 100 ms. This period during which audiovisual effects are delayed can increase the realism of participating in the virtual environment because, as known to a person of skill in the art, somatosensory signaling often leads audiovisual signaling (e.g., a person may feel contact with an object before perceiving a sound associate with that contact).

Similar to the client device 2204, the haptic data stream source 2208 and the environment engine 2206 can likewise be implemented in whole or in part in software. In particular, both systems may leverage processing and memory resources (identified as the resources 2206a and the resources 2208a) to instantiate different purpose configured instances of software. These foregoing examples are not exhaustive; a system as described herein can be configured in a number of suitable ways. For example, the RSTS device 2210 and the client device 2204 may communicate over a local wireless protocol such as Bluetooth or Wi-Fi or Ultrawide Band. In other cases, the RSTS device 2210 and the client device 2204 may communicate over one or more networks, which may include the open internet. In such examples, user-specific thresholds defining limits or max/min thresholds to stimulation (as described herein) may ensure that any interference with instructions sent over the network do not result in painful or otherwise unpleasant experiences in the user.

In some cases, the virtual environment 2202 can communicate with one or both of the device 2204 and the RSTS device 2210 over a network, which may be a private network, a cellular network, a Wi-Fi network, an intranet, or may include the open Internet. In many embodiments, authentication and authorization operations may be performed such that stimulation of a user by the RSTS device 2210 cannot be incidentally triggered or otherwise intercepted/interfered with.

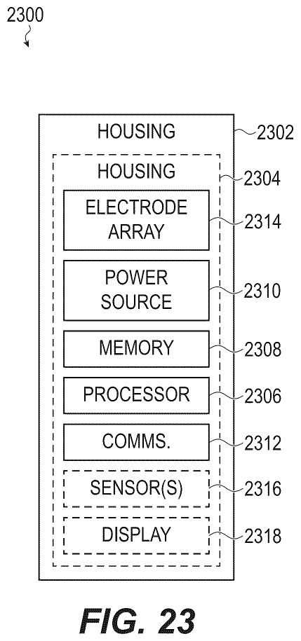

FIG. 23 depicts a simplified system diagram of a referred sensation wearable configured to provide sensory feedback to a wearer. The referred sensation wearable 2300 may be an Referred sensation wearable 2302 such as described in reference to FIG. 2. The Referred sensation wearable 2302 includes a housing 2304 the encloses and supports internal components of the Referred sensation wearable 2302. As noted with respect to other embodiments described herein, the Referred sensation wearable 2302 and in particular the housing 2304 of the Referred sensation wearable 2302 can take a number of suitable form factors. In many cases, the housing 2304 takes a shape configured to contour to a portion of a limb or finger of a user, so as to at least partially circumscribe a portion or cross-section of a sensory nerve within that limb or finger that may be recruited to provide referred sensation as described herein. Example form factors that the Referred sensation wearable 2302 may take include, but are not limited to, finger rings, wrist cuffs, neck cuffs, ankle cuffs, sleeves, partial sleeves, gloves, glovelets, fingerless gloves, toe rings, ear hooks, and so on.

As with many embodiments described herein, the housing 2304 of the Referred sensation wearable 2302 can enclose and support one or more electrical circuits configured to perform, coordinate, or otherwise execute or cause to be executed one or more operations or functions of the Referred sensation wearable 2302. In the illustrated embodiment, the Referred sensation wearable 2302 includes a processing resource 2306 and a memory resource 2308. The processing resource 2306 and the memory resource 2308 can, a described elsewhere herein, can cooperate to instantiate software configured to communicate with other electronic devices (e.g., personal cellular phones, gaming consoles, and the like) and configured to stimulate recruited nerves.

In many embodiments, although not expressly required, a power source 2310 may also be included in the housing 2304 to provide power to the various elements of the Referred sensation wearable 2302. The power source 2310 can be a battery, a Peltier element, a piezoelectric element, a solar array, a tethered connection to another electronic device or power source, an inductive or resonant wireless power transfer system, or any other suitable power source.

The Referred sensation wearable 2302 also includes one or more communications systems 2312 for communicating with other electronic device and/or for receiving signals that indicate sensory impressions should be evoked. Example communications systems that may be included in the communications systems 2312 include by are not limited to: Bluetooth; Wi-Fi; cellular (e.g., 5G NR); 433 Mhz radios; software-defined radios; infrared communications systems; acoustic communications systems; and so on.

The Referred sensation wearable 2302 also includes an electrode array 2314. The electrode array 2314 can be disposed on or through an external surface of the housing 2304. The electrode array 2314 is oriented so as to interface with and/or contact a surface of the user's skin. For example, in a ring form factor, the external surface through which the electrode array 2314 extends to contact the user's skin is the internal diameter of the ring. Similarly, in a wrist cuff embodiment the external surface through which the electrode array 2314 extends to contact the user's skin is the internal surface of the cuff.

The electrode array 2314 can include many different individual electrodes, each of which may be configured to operate as an anode (negative signal terminal) or a cathode (positive signal terminal). In some cases, multiple electrodes may serve as anode to a single cathode. In other cases, multiple electrodes can serve as cathode to a number of anodes; any suitable combination of electrodes may be selected. The electrode array 2314 can be disposed in a repeating pattern with any number of individual electricals making up the same. In some examples, the electrode array 2314 includes electrodes all formed form the same material (e.g., a conductive material, such as a metal or metal alloy) and formed in the same shape, such as a square or rectilinear shape. In other cases, different electrodes may be formed from different metals or alloys and/or in different shapes. Some electrodes of the electrode array 2314 can have a different surface area than other electrodes and may be formed from different materials.

In many embodiments, the electrode array 2314 may be formed from a biocompatible metal material, such gold. In some cases, metals likely to trigger an allergic response in some users may be avoided (e.g., nickel, silver, and so on). In some cases, metal alloys may be selected specifically for oxidation resistance. Example electrode materials and alloys includes, but is not limited to: copper alloys; gold alloys (e.g., AgNW, AgCl); tungsten alloys (e.g., CuNW); titanium alloys; and so on.

In some constructions, the electrode array 2314 includes rigid electrodes. In other cases, the electrode array 2314 includes flexible and/or polymerized electrodes. In some cases, the electrode array 2314 may extend proud of the exterior surface of the housing 2304 so as to ensure contact with the user's skin. These foregoing examples are not exhaustive; many electrode configurations are possible.

The Referred sensation wearable 2302 can also optionally include one or more sensors 2316 and/or one or more displays 2318. In some cases, the display 2318 may be an indicator or status light whereas in other cases, a two dimensional display (e.g., OLED, ePaper, LCD, and so on) may be used or included.

In some embodiments, the referred sensation wearable 2302 can include sensors such as temperature sensors, impedance sensors, humidity sensors, conductivity sensors, gyroscopes, accelerometers, and the like. Output from these sensors (among the sensors 2316) can be used to inform or update a stimulation profile and/or a calibration profile as described herein. In other cases output from the sensors 2316 can be leveraged by the processor or processing resource 2306 to trigger a calibration or re-calibration process or operation.

For example, a body impedance measurement can be used to inform an envelope for stimulation that may be updated in real time and/or modified over time. For example, a user's skin impedance and/or body impedance may change over the course of a day; in such cases, output form an impedance sensor or sensing system can inform whether to increase magnitude of stimulation or decrease magnitude of stimulation (as one example mutable property; other properties may be modified as well or in place in other embodiments) so as to provide a consistent sensory impression experience given varying stimulation conditions.

These foregoing embodiments depicted in FIG. 23 and the various alternatives thereof and variations thereto are presented, generally, for purposes of explanation, and to facilitate an understanding of various configurations and constructions of a referred sensation wearable implemented as an RSTS device, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

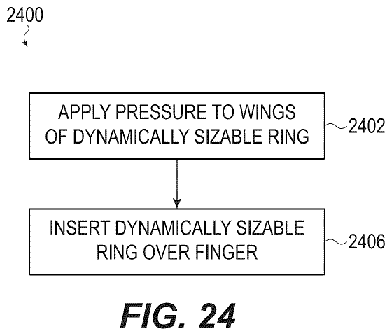

FIG. 24 is a flowchart depicting example operations of a method of wearing a referred sensation wearable as described herein. The method 2400 includes operation 2402 at which pressure is applied to increase a sizable ring. At operation 2404, a finger may be inserted into a finger aperture thereof.

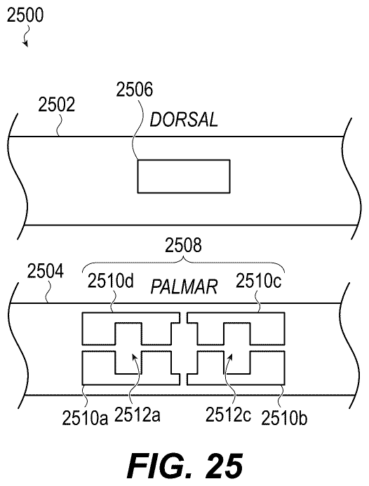

FIG. 25 is a plan view of dorsal and palmar electrode patterns defining optical sensing apertures. The figure illustrates: a pair of electrodes 2500; an upper ring part 2502; a lower ring part 2504; a dorsal electrode 2506; a set of palmar electrodes 2508; the individual palmar electrodes 2510a-d; the sensing apertures 2512a-c. The sensing apertures can facilitate sensing through the electrode array, such as for optical sensing (e.g., PPG, heart rate, respiration rate, medical optical sensing, blood oxygenation, and so on), or any other sensing type. In some cases, antenna can be disposed within the apertures.

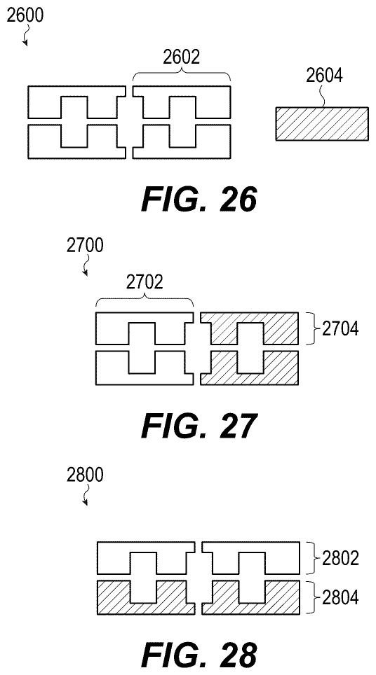

FIG. 26 depicts a schematic view of an electrode pattern 2600 associated with selectable anode and cathode assignments. An electrode group 2602 may be configured as a first switchable node including interdigitated electrode features. An electrode block 2604 may be configured as a second switchable node. In an operational configuration, the electrode group 2602 may be assigned an anode role while the electrode block 2604 may be assigned a cathode role, or a reciprocal assignment may be applied.

FIG. 27 depicts a schematic view of an electrode pattern 2700 associated with paired electrode group operation. A first electrode group 2702 may be configured as a first switchable node including opposing interdigitated features. A second electrode group 2704 may be configured as a second switchable node. The first electrode group 2702 may be assigned an anode role and the second electrode group 2704 may be assigned a cathode role to define a lateral stimulation vector across adjacent cross sections.

FIG. 28 depicts a schematic view of an electrode pattern 2800 associated with stacked electrode pairing. A first electrode group 2802 may be configured as a first switchable node positioned above a second electrode group. A second electrode group 2804 may be configured as a second switchable node positioned below the first electrode group 2802. The first electrode group 2802 may be assigned an anode role and the second electrode group 2804 may be assigned a cathode role to define a superior-inferior stimulation vector, although reversed polarity assignments may be used.

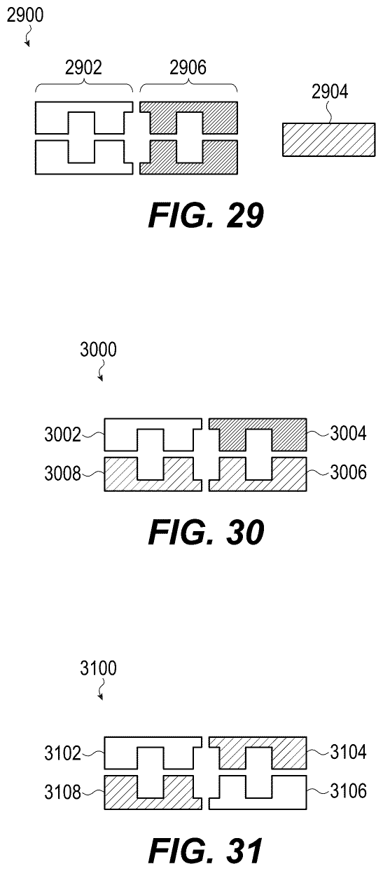

FIG. 29 depicts a schematic view of an electrode pattern 2900 configured for alternative node selection. A first electrode group 2902 may be configured as a first switchable node. An electrode block 2904 may be configured as a reference electrode, a guard electrode, or an auxiliary cathode node. A second electrode group 2906 may be configured as a second switchable node. The first electrode group 2902 and the second electrode group 2906 may be alternately assigned anode and cathode roles while the electrode block 2904 may be held at a fixed potential or a floating potential.

FIG. 30 depicts a schematic view of an electrode pattern 3000 configured for multi-node stimulation. A first electrode element 3002 may be configured as a first anode node. A second electrode element 3004 may be configured as a first cathode node. A third electrode element 3006 may be configured as a second cathode node or a switchable node paired with the first electrode element 3002. A fourth electrode element 3008 may be configured as a second anode node or a switchable node paired with the second electrode element 3004, such that multiple current paths may be selectively defined.

FIG. 31 depicts a schematic view of an electrode pattern 3100 configured for cross-paired polarity assignments. A first electrode element 3102 may be configured as a first anode node. A second electrode element 3104 may be configured as a first cathode node. A third electrode element 3106 may be configured as a second anode node positioned opposite the second electrode element 3104. A fourth electrode element 3108 may be configured as a second cathode node positioned opposite the first electrode element 3102, thereby supporting diagonal or alternating stimulation vectors across an electrode array.

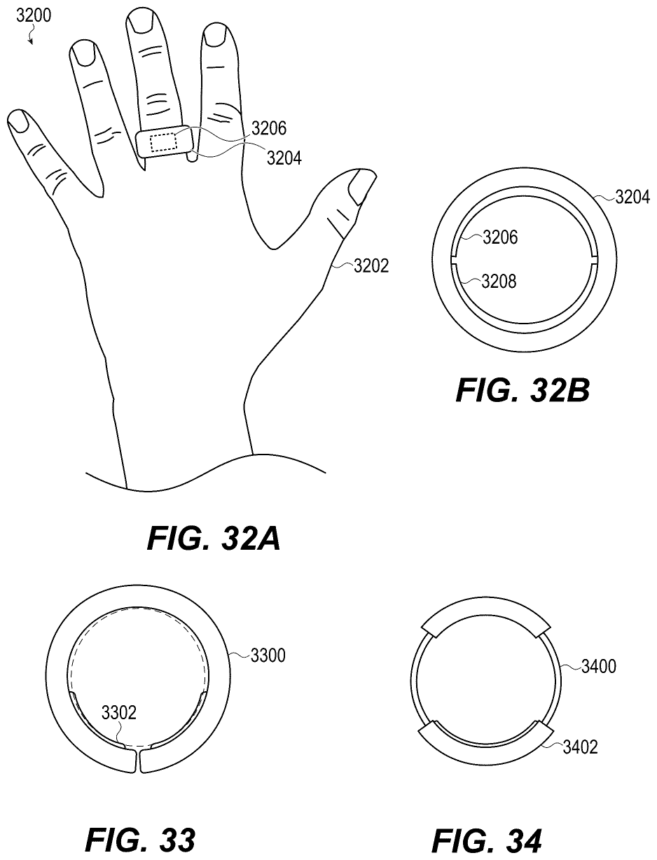

Many embodiments described herein relate to referred stimulation devices having housings that extend from an annular structure defining a finger aperture. In other cases, this may not be required. For example, in some cases, electronics associated with a referred sensation device or a neural haptic device can be disposed entirely within an annular housing taking the shape of a finger ring. An example 3200 is depicted in FIGS. 32A-32B shows a neural haptic device worn by a user 3202 on a finger. The neural haptic device 3204 depicts electrodes 3206, 3208 that may be configured to conductively engage with a skin surface of the user 3202 to provide stimulation or neural haptic feedback as described herein.

In some embodiments, the ring embodiment of FIG. 32 may have a fixed size and different users may select different sizes to ensure appropriate mechanical and electrical connection/interface with the skin surface(s) of a wearer. However in some cases, a ring may be resizable and/or may include a partially separable housing with an elastic member, such as shown in FIGS. 33-34. In these examples, a wearable device can have a divided housing configured to expand for accommodating multiple sizes. FIG. 33 depicts a neural haptic device 3300 with a single break and elastic member that leverage tension to of the elastic member to enclose around a finger of a wearer to retain contact between the wearer and an electrode 3302. FIG. 34 depicts a housing of a neural haptic device 3400 with multiple breaks, such as an upper portion and a lower portion 3402. In these examples, the upper portion and lower portion can include cooperating electronics, such as a controller in an upper portion and a batter in the lower portion. Many configurations are possible, including unibody ring structures such as described above in respect of FIG. 32 and FIG. 13.

These foregoing embodiments depicted in FIGS. 1-34 and the various alternatives thereof and variations thereto are presented, generally, for purposes of explanation, and to facilitate an understanding of various configurations and constructions of a referred sensation wearable implemented as an RSTS device with a variable or resizable ring aperture, such as described herein. However, it will be apparent to one skilled in the art that some of the specific details presented herein may not be required in order to practice a particular described embodiment, or an equivalent thereof.

Thus, it is understood that the foregoing and following descriptions of specific embodiments are presented for the limited purposes of illustration and description. These descriptions are not targeted to be exhaustive or to limit the disclosure to the precise forms recited herein. To the contrary, it will be apparent to one of ordinary skill in the art that many modifications and variations are possible in view of the above teachings.

For example, in some embodiments, a generative artificial intelligence system or a large language model may be executed at a host device communicably coupled to a referred sensation wearable as described herein. A user-specific calibration profile and one or more stimulation profiles may be provided as input constraints or context. Physiological data, historical user feedback, and a current virtual event stream may be provided as additional inputs to generate a candidate stimulation plan for a wearing session.

In other embodiments, a stimulation plan may be generated as a parameter sequence defining electrode pair assignments, anode and cathode role schedules, waveform limits, amplitude ramps, duty-cycle schedules, pulse width selections, and temporal offsets relative to audio rendering or visual rendering. The stimulation plan may be filtered by comfort thresholds stored in memory. The stimulation plan may be updated during a session based on impedance sensing or explicit user feedback.

In additional embodiments, a large language model may be configured to generate an output data object operationally coupled to a client device and the referred sensation wearable. The output data object may be structured as a JSON-format command set or a time-stamped event table mapping sensory impression modalities and sensory impression sites to stimulation profiles. The output data object may be transmitted over a wireless link for parsing by a controller within a housing.

In further embodiments, the output data object may be generated in response to a natural language request provided through a graphical user interface. The natural language request may specify a target modality, a target site, a duration window, or a priority class associated with a notification event. The large language model may be constrained to select only stimulation parameters stored within an approved parameter envelope associated with the calibration profile.

As used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

One may appreciate that although many embodiments are disclosed above, that the operations and steps presented with respect to methods and techniques described herein are meant as exemplary and accordingly are not exhaustive. One may further appreciate that alternate step order or fewer or additional operations may be required or desired for particular embodiments.

Although the disclosure above is described in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the some embodiments of the invention, whether or not such embodiments are described and whether or not such features are presented as being a part of a described embodiment. Thus, the breadth and scope of the present invention should not be limited by any of the above-described exemplary embodiments but is instead defined by the claims herein presented.

In addition, it is understood that organizations and/or entities responsible for the access, aggregation, validation, analysis, disclosure, transfer, storage, or other use of private data such as described herein will preferably comply with published and industry-established privacy, data, and network security policies and practices. For example, it is understood that data and/or information obtained from remote or local data sources, only on informed consent of the subject of that data and/or information, should be accessed aggregated only for legitimate, agreed-upon, and reasonable uses.

As used herein, the term “processing resource” refers to any physical and/or virtual electronic device or machine component, or set or group of interconnected and/or communicably coupled physical and/or virtual electronic devices or machine components, suitable to execute or cause to be executed one or more arithmetic or logical operations on digital data.

Example processing resources contemplated herein include, but are not limited to: single or multi-core processors; single or multi-thread processors; purpose-configured co-processors (e.g., graphics processing units, motion processing units, sensor processing units, and the like); volatile or non-volatile memory; application-specific integrated circuits; field-programmable gate arrays; input/output devices and systems and components thereof (e.g., keyboards, mice, trackpads, generic human interface devices, video cameras, microphones, speakers, and the like); networking appliances and systems and components thereof (e.g., routers, switches, firewalls, packet shapers, content filters, network interface controllers or cards, access points, modems, and the like); embedded devices and systems and components thereof (e.g., system(s)-on-chip, Internet-of-Things devices, and the like); industrial control or automation devices and systems and components thereof (e.g., programmable logic controllers, programmable relays, supervisory control and data acquisition controllers, discrete controllers, and the like); vehicle or aeronautical control devices systems and components thereof (e.g., navigation devices, safety devices or controllers, security devices, and the like); corporate or business infrastructure devices or appliances (e.g., private branch exchange devices, voice-over internet protocol hosts and controllers, end-user terminals, and the like); personal electronic devices and systems and components thereof (e.g., cellular phones, tablet computers, desktop computers, laptop computers, wearable devices); personal electronic devices and accessories thereof (e.g., peripheral input devices, wearable devices, implantable devices, medical devices and so on); and so on. It may be appreciated that the foregoing examples are not exhaustive.

More generally, as described herein, the term “processor” refers to any software and/or hardware-implemented data processing device or circuit physically and/or structurally configured to instantiate one or more classes or objects that are purpose-configured to perform specific transformations of data including operations represented as code and/or instructions included in a program that can be stored within, and accessed from, a memory. This term is meant to encompass a single processor or processing unit, multiple processors, multiple processing units, analog or digital circuits, or other suitably configured computing element or combination of elements. Similarly, as described herein, the term “memory” refers to any software and/or hardware-implemented data storage device or circuit physically and/or structurally configured to store digital information, whether structured or unstructured.

Further, the foregoing examples and description of instances of purpose-configured software, whether accessible via Application Programming Interface (API) as a request-response service, an event-driven service, or whether configured as a self-contained data processing service are understood as not exhaustive. In other words, a person of skill in the art may appreciate that the various functions and operations of a system such as described herein can be implemented in a number of suitable ways, developed leveraging any number of suitable libraries, frameworks, first or third-party APIs, local or remote databases (whether relational, NoSQL, or other architectures, or a combination thereof), programming languages, software design techniques (e.g., procedural, asynchronous, event-driven, and so on or any combination thereof), and so on. The various functions described herein can be implemented in the same manner (as one example, leveraging a common language and/or design), or in different ways. In many embodiments, functions of a system described herein are implemented as discrete microservices, which may be containerized or executed/instantiated leveraging a discrete virtual machine, that are only responsive to authenticated API requests from other microservices of the same system. Similarly, each microservice may be configured to provide data output and receive data input across an encrypted data channel. In some cases, each microservice may be configured to store its own data in a dedicated encrypted database; in others, microservices can store encrypted data in a common database; whether such data is stored in tables shared by multiple microservices or whether microservices may leverage independent and separate tables/schemas can vary from embodiment to embodiment. As a result of these described and other equivalent architectures, it may be appreciated that a system such as described herein can be implemented in a number of suitable ways. For simplicity of description, many embodiments that follow are described in reference an implementation in which discrete functions of the system are implemented as discrete microservices. It is appreciated that this is merely one possible implementation.

What is claimed is:

1. A neural haptic wearable configured to be worn on a finger of a wearer and comprising:
an adaptive compression member configured to define at least a portion of a finger aperture;
a housing coupled to the adaptive compression member relative to the finger aperture;
an elastic element coupled to the adaptive compression member;
a first compression leverage wing and a second compression leverage wing movable relative to the housing and configured to apply tension to the elastic element thereby changing a dimension of the finger aperture when the first compression leverage wing and the second compression leverage wing each respectively receive a respective applied force directed toward the housing; and
an electrode array defined within an interior surface of the adaptive compression member that at least in part defines the finger aperture, wherein tension of the elastic element maintains the adaptive compression member and electrode array in contact with the finger.

2. The neural haptic wearable of claim 1, the electrode array comprising a palmar electrode and a dorsal electrode.

3. The neural haptic wearable of claim 1, the electrode array comprising at least three electrodes.

4. The neural haptic wearable of claim 1, the adaptive compression member comprising a first part and a second part separated by a first introduced compliance void and a second introduced compliance void.

5. The neural haptic wearable of claim 1, the housing defining first and second recesses configured to receive the first and second compression leverage wings.

6. The neural haptic wearable of claim 1, the elastic element comprising an elastic band coupled to the adaptive compression member.

7. The neural haptic wearable of claim 1, the housing integrally formed with the adaptive compression member.

8. The neural haptic wearable of claim 1, the adaptive compression member comprising a raceway configured to route conductors coupling to the electrode array.

9. A neural haptic wearable comprising:
a component housing;
an adaptive compression ring defining a finger aperture, coupled to the component housing, and comprising:
a reduced thickness region to introduce flexibility within the adaptive compression ring;
a compression lever adjacent the reduced thickness region and extending at least in part from the adaptive compression ring, the compression lever positioned to be received within a recess of the component housing in response to an application of force;
an electrode array conductively coupled to a controller disposed within the component housing and disposed to:
face inward relative to the finger aperture; and
contact a skin surface such that when the adaptive compression ring is in a contracted configuration, the electrode array maintains electrical contact with the skin surface.

10. The neural haptic wearable of claim 9, the component housing comprises an obround enclosure shape.

11. The neural haptic wearable of claim 9, the component housing comprises a spherical enclosure shape.

12. The neural haptic wearable of claim 9, the housing having a polygonal enclosure shape.

13. The neural haptic wearable of claim 9, further comprising an elastic tensioner coupled to the adaptive compression ring.

14. The neural haptic wearable of claim 9, the adaptive compression ring defining one or more sensing apertures configured to permit optical sensing through the electrode array.

15. The neural haptic wearable of claim 14, at least one antenna disposed within a sensing aperture of the one or more sensing apertures.

16. The neural haptic wearable of claim 9, the controller configured to assign an anode role and a cathode role to different electrodes of the electrode array.

17. The neural haptic wearable of claim 9, the controller configured to be wirelessly coupled with at least one host device comprising a phone, a computing appliance, a gaming device, or a controller.

18. A neural haptic wearable electronic device comprising:
a ring body configured to be worn as a finger ring and defining a finger aperture;
an electrode array disposed along an internal surface of the ring body to contact skin within the finger aperture, the finger aperture sized to maintain electrical contact between the electrode array and the skin.

19. The neural haptic wearable electronic device of claim 18, comprising a housing positioned on an upper side of the ring body to encourage a predetermined rotational orientation of the ring body relative to finger anatomy.

20. The neural haptic wearable electronic device of claim 18, the electrode array comprising spring-loaded electrically conductive contacts configured to apply a retaining force against the skin.
